(19) United States
(12) Patent Application Publication
(10) Pub. No.: US 2026/0371681 A1
(43) Pub. Date: Nov. 19, 2026

(54) STRAIN ENGINEERING FOR COMPLEMENTARY FIELD-EFFECT TRANSISTOR DEVICES

(71) Applicant: Taiwan Semiconductor Manufacturing Co., Ltd., Hsinchu (TW)

(72) Inventors: Yu-Hsien Chiang, Hsinchu (TW); Zhi-Chang Lin, Zhubei City (TW); Ku-Feng Yang, Baoshan Township (TW); Szuya Liao, Zhubei (TW)

(21) Appl. No.: 19/750,381

(22) Filed: Jul. 22, 2026

Related U.S. Application Data
(63) Continuation of application No. 19/177,132, filed on Apr. 11, 2025.
(60) Provisional application No. 63/720,495, filed on Nov. 14, 2024.

(51) Int. Cl. H10D 64/01; H10D 30/00; H10D 30/01; H10D 30/43; H10D 30/69; H10D 62/10; H10D 62/13; H10D 84/01; H10D 84/03; H10D 84/85; H10D 88/00

(52) U.S. Cl. CPC H10D 64/017; H10D 30/014; H10D 30/0191; H10D 30/43; H10D 30/502; H10D 30/797; H10D 62/122; H10D 62/151; H10D 84/017; H10D 84/0186; H10D 84/038; H10D 84/851; H10D 88/00

(57) ABSTRACT

A method of forming a semiconductor device includes: forming a layer stack over a fin by successively forming a dielectric material, a sacrificial material, a first semiconductor material, and a second semiconductor material over the fin; forming a dummy gate structure over the layer stack; forming source/drain regions on opposing sides of the dummy gate structure; forming an inter-layer dielectric layer over the source/drain regions around the dummy gate structure; removing the dummy gate structure to expose a first portion of the layer stack; after removing the dummy gate structure, selectively removing the sacrificial material in the first portion of the layer stack, where after the selectively removing, the first semiconductor material and the second semiconductor material in the first portion of the layer stack form a first channel layer and a second channel layer, respectively; and forming a replacement gate structure around the first and the second channel layers.

### PRIORITY CLAIM AND CROSS-REFERENCE

This application is a continuation of U.S. patent application Ser. No. 19/177,132, filed Apr. 11, 2025 and entitled “Strain Engineering for Complementary Field-Effect Transistor Devices,” which claims priority to U.S. Provisional Patent Application No. 63/720,495, filed Nov. 14, 2024 and entitled “Strain Engineering with SGIO Substrate for Sequential CFET,” which applications are hereby incorporated by reference in their entireties.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

Recently, vertically stacked transistor devices, such as complementary field-effect transistor (CFET) devices, provide a promising new architecture that achieves improved integration density by forming nanostructure field-effect transistors (NSFETs) that are vertically stacked over a substrate. Various aspects of this new architecture need to be studied and improved to achieve better device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2A, 2B, 3, 4, 5, 6, 7A, 7B, 8A, 8B, 9A, 9B, 9C, 10A, 10B, 10C, 11A, 11B, 11C, 12A, 12B, 13A, 13B, 13C, 14A, 14B, 15A, 15B, 16A, 16B, 17A, 17B, 17C, and 17D illustrate cross-sectional views of a complementary field-effect transistor (CFET) device at various stages of manufacturing, in accordance with an embodiment.

FIGS. 18A and 18B illustrate cross-sectional views of a CFET device, in accordance with another embodiment.

FIGS. 19, 20, 21, 22A, and 22B illustrate cross-sectional views of a CFET device at various stages of manufacturing, in accordance with another embodiment.

FIGS. 23A and 23B illustrate cross-sectional views of a CFET device, in accordance with another embodiment.

FIGS. 24, 25A, and 25B illustrate cross-sectional views of a CFET device at various stages of manufacturing, in accordance with yet another embodiment.

FIGS. 26A and 26B together illustrate a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

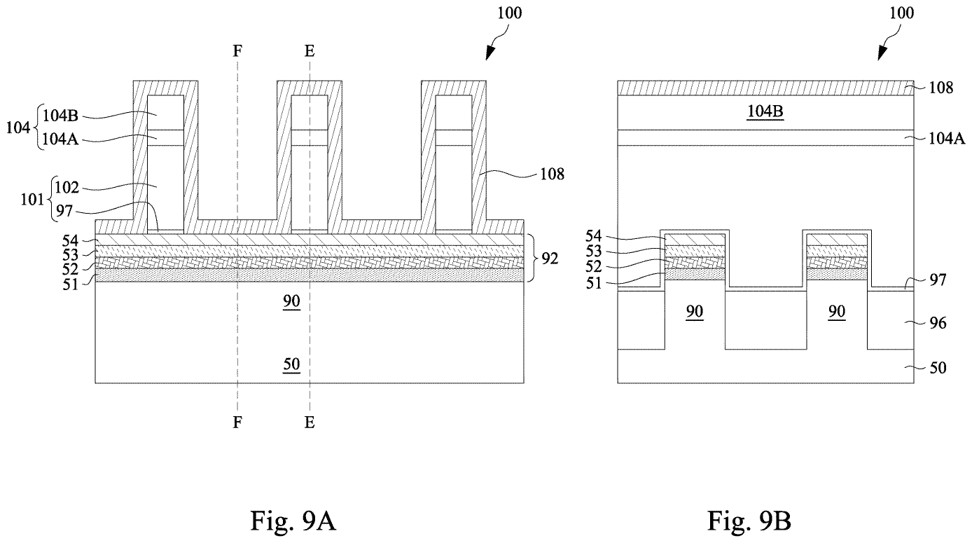

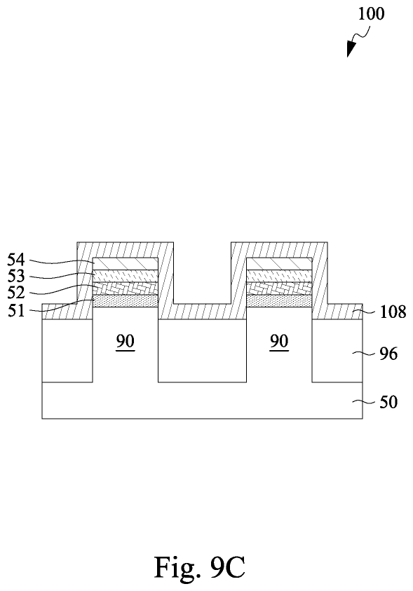

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refers to the same or similar component formed by the same or similar formation process using the same or similar material(s). In addition, figures with the same numeral but different alphabets (e.g., FIGS. 9A-9C) illustrate different views of the same device at the same stage of processing.

In some embodiments, a first interconnect structure of a first nanostructure field-effect transistor (NSFET) device is bonded to a second interconnect structure of a second NSFET device to form a complementary field-effect transistor (CFET) device. A channel region of at least one of the first NSFET device and the second NSFET device has a dual-layered structure that includes a first channel layer (e.g., silicon germanium) and a second channel layer (e.g., silicon) in contact with the first channel layer, where the first channel layer and the second channel layer are formed of different semiconductor materials. The dual-layered channel regions of the CFET device achieve enhanced carrier mobility through band energy alignment. The engineered band alignment between the SiGe and Si layers creates optimized energy barriers and carrier confinement regions, resulting in reduced carrier scattering and lower effective mass for both electrons and holes. This complementary enhancement of carrier transport properties in the dual channel structure enables improved switching speeds, lower power consumption, and overall better device performance in the resulting semiconductor device.

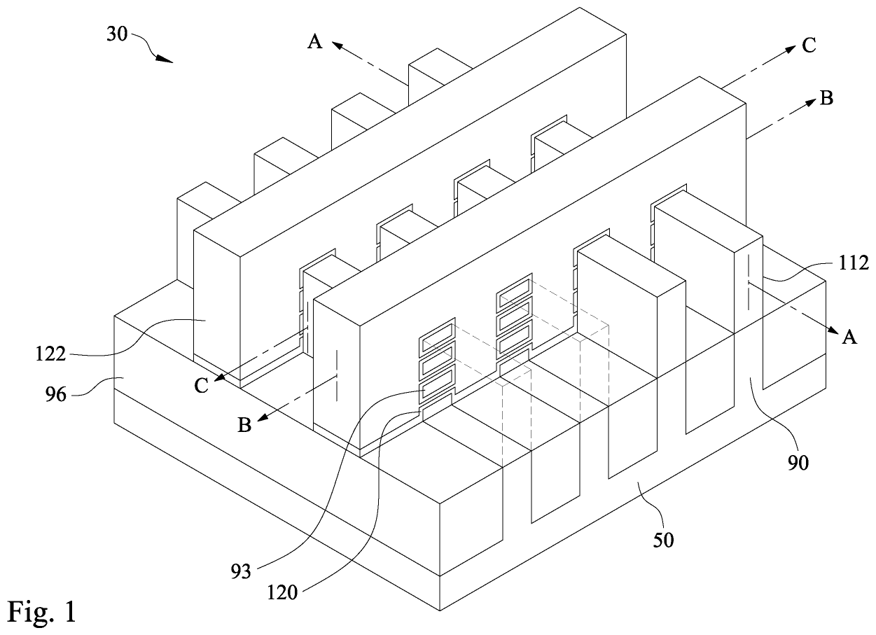

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of channel region 93 (e.g., nanowires, or nanosheets) are formed over the fins 90 and between source/drain regions 112. Isolation regions 96 are formed on opposing sides of the fins 90. A gate dielectric layer 120 is formed around the channel regions 93. Gate electrodes 122 are over and around the gate dielectric layer 120.

FIG. 1 further illustrates reference cross-sections that are used in later figures. Cross-section A-A is along a longitudinal axis of the fin 90 and is in a direction of, for example, a current flow between the source/drain regions 112 of the NSFET device. Cross-section B-B is perpendicular to cross-section A-A and is along a longitudinal axis of the gate electrode 122. Cross-section C-C is parallel to cross-section B-B and extends through source/drain regions 112 of the NSFET device. Subsequent figures may refer to these reference cross-sections for clarity.

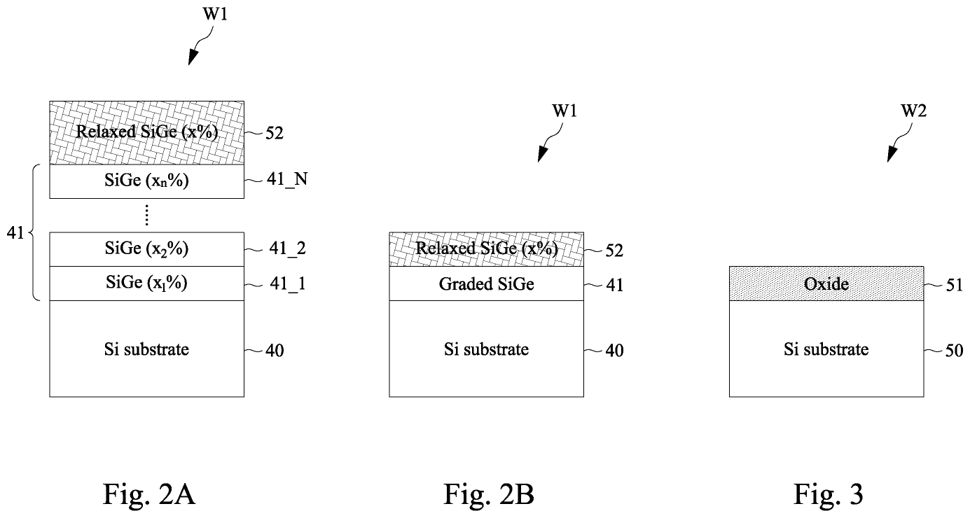

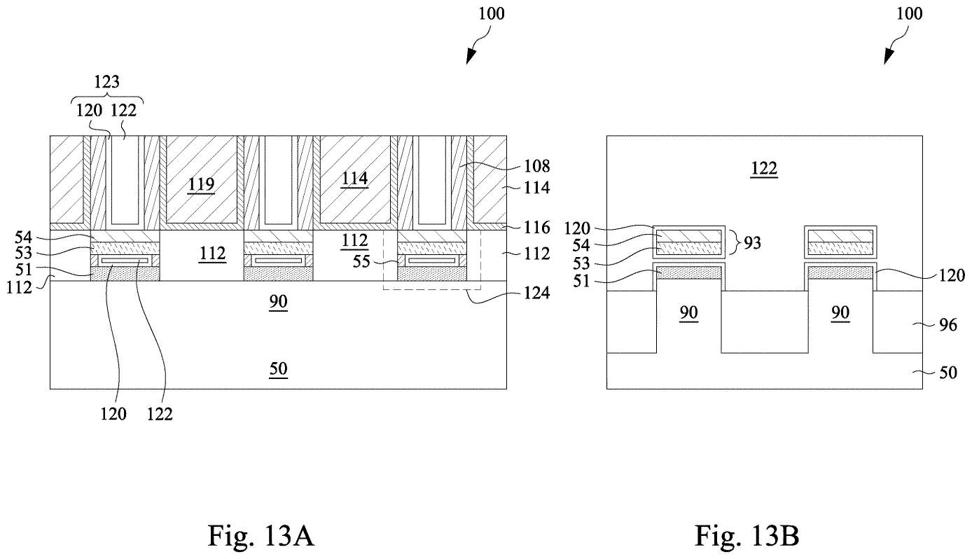

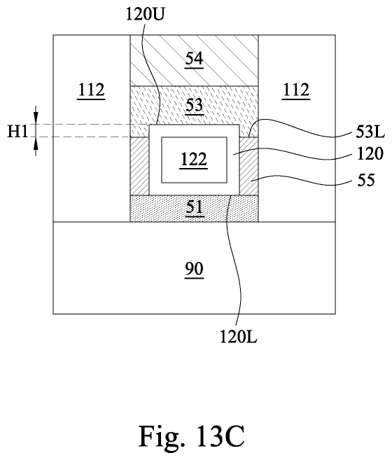

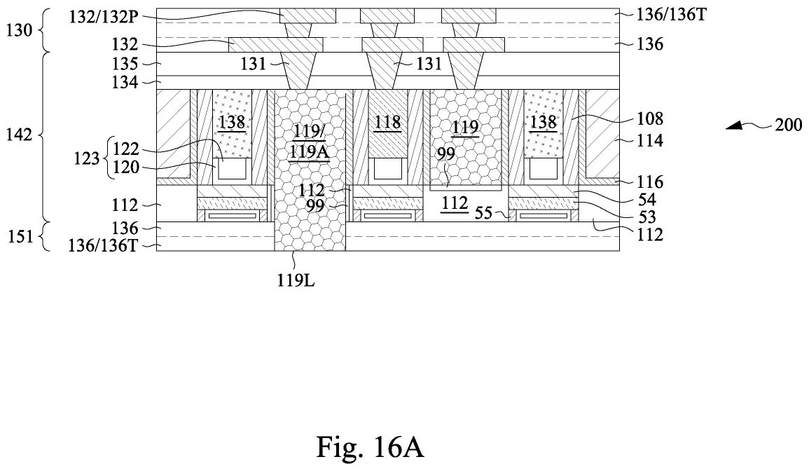

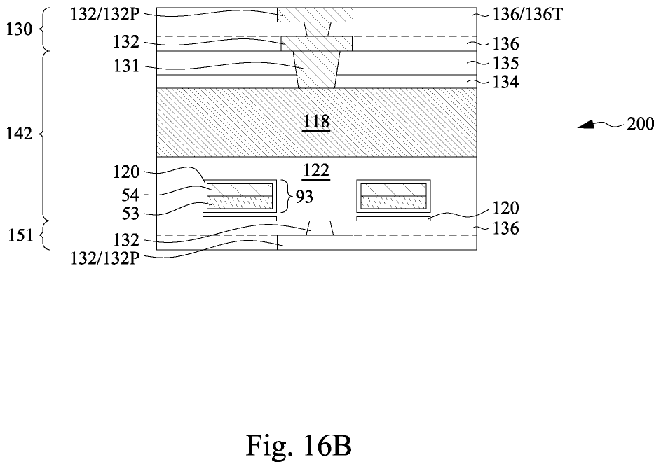

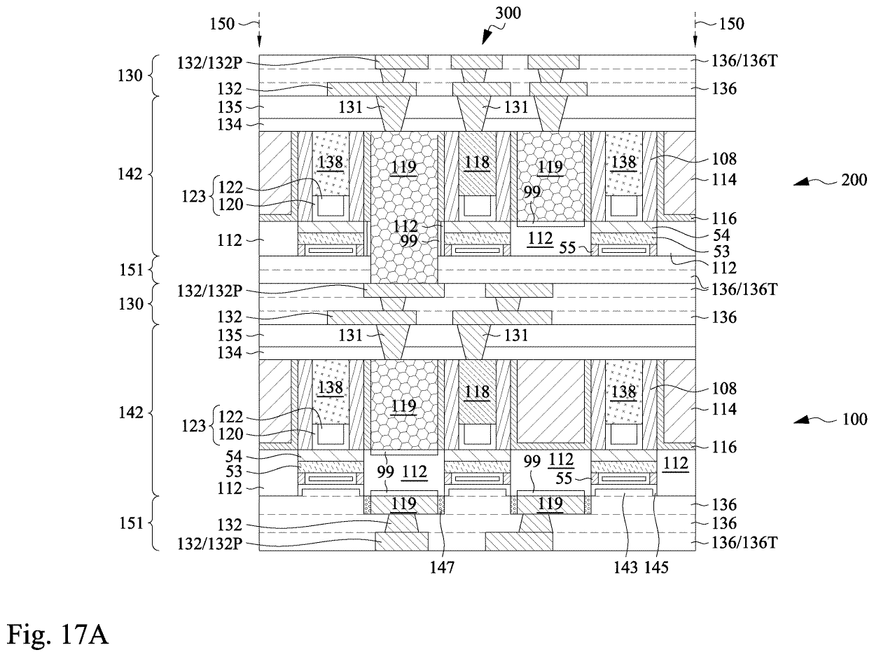

FIGS. 2A, 2B, 3, 4, 5, 6, 7A, 7B, 8A, 8B, 9A, 9B, 9C, 10A, 10B, 10C, 11A, 11B, 11C, 12A, 12B, 13A, 13B, 13C, 14A, 14B, 15A, 15B, 16A, 16B, 17A, 17B, 17C, and 17D illustrate cross-sectional views of a complementary field-effect transistor (CFET) device 300 at various stages of manufacturing, in accordance with an embodiment. In particular, FIGS. 2A, 2B, 3, 4, 5, 6, 7A, 7B, 8A, 8B, 9A, 9B, 9C, 10A, 10B, 10C, 11A, 11B, 11C, 12A, 12B, 13A, 13B, 13C, 14A, 14B, 15A, and 15B illustrate cross-sectional views of an NSFET device 100 at various stages of processing, in an embodiment. FIGS. 16A and 16B illustrate cross-sectional views of an NSFET device 200, in an embodiment. The NSFET device 100 is then bonded to the NSFET device 200 to form the CFET device 300, as illustrated by the cross-sectional views of FIGS. 13A and 13B.

In FIG. 2A, a substrate 40 is provided. The substrate 40 may be a semiconductor substrate, such as a bulk semiconductor, a semiconductor-on-insulator (SOI) substrate, or the like, which may be doped (e.g., with a p-type or an n-type dopant) or undoped. The substrate 40 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 40 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Next, a graded silicon germanium layer 41 and a relaxed silicon germanium layer 52 are formed (e.g., epitaxially formed) successively on the substrate 40. In some embodiments, the graded silicon germanium layer 41 includes a plurality of sublayers 41_1, 41_2, . . . , and 41_N, where each of the sublayers 41_1, 41_2, . . . , and 41_N is a layer of silicon germanium (Si₁₋ₓGeₓ, where x is in a range between 0 and 1) with a respective concentration (e.g., atomic percentage) of germanium. The concentrations (e.g., atomic percentages) of the sublayers 41_1, 41_2, . . . , and 41_N are denoted as x₁%, x₂%, . . . , and xₙ%, respectively, where x₁%<x₂%< . . . <xₙ%. In other words, there is a gradient in the concentrations of the germanium in the sublayers 41_1, 41_2, . . . , and 41_N.

In some embodiments, each of the plurality of sublayers 41_1, 41_2, . . . , and 41_N is formed by a suitable formation method such as chemical vapor deposition (CVD) using a silicon-containing precursor (e.g., silane) and a germanium-containing precursor (e.g., germane). In an embodiment, the ratio between the flow rates of the silicon-containing precursor and the germanium-containing precursor is fixed at a respective value during the formation of each of the sublayers 41_1, 41_2, . . . , and 41_N, such that each of the sublayers 41_1, 41_2, . . . , and 41_N has a uniform germanium concentration. In addition, for each additional sublayer of the graded silicon germanium layer 41 formed over the substrate 40, the ratio between the flow rates of the silicon-containing precursor and the germanium-containing precursor is adjusted to increase the percentage of the germanium-containing precursor, such that the germanium concentration of the additional sublayer is higher than that of the previous sublayer of the graded silicon germanium layer 41. In the illustrated embodiment of FIG. 2A, there is a step change in the germanium concentration between adjacent sublayers of the graded silicon germanium layer 41. This is, of course, merely a non-limiting example. In some embodiments, the ratio between the flow rates of the silicon-containing precursor and the germanium-containing precursor is changed continuously during the formation of the graded silicon germanium layer 41, such that the graded silicon germanium layer 41 has a continuously changing (e.g., increasing continuously along a vertical direction away from the substrate 40) germanium concentration between a lower surface contacting the substrate 40 and an upper surface distal from the substrate 40.

Next, the relaxed silicon germanium layer 52 is formed on the graded silicon germanium layer 41. In some embodiments, the relaxed silicon germanium layer 52 is formed using a suitable formation method such as CVD, and the ratio between the flow rates of the silicon-containing precursor and the germanium-containing precursor is adjusted (e.g., to a fixed value) to achieve a germanium concentration (e.g., atomic percentage) of x % which is higher than a highest germanium concentration (e.g., xₙ%) of the graded silicon germanium layer 41 (e.g., x %>xₙ%). In some embodiments, the germanium concentration x % of the relaxed silicon germanium layer 52 is between about 25% and about 40%. The graded silicon germanium layer 41 allows the relaxed silicon germanium layer 52 with a relatively high germanium concentration to be formed over the substrate 40 with little or no defect. After the relaxed silicon germanium layer 52 is formed, the structure shown in FIG. 2A may be referred to as a wafer structure W1. For ease of illustration, the sublayers 41_1, 41_2, . . . , and 41_N of the graded silicon germanium layer 41 are not individually illustrated in subsequent figures, and the wafer structure W1 in FIG. 2A is illustrated as the wafer structure W1 in FIG. 2B.

FIG. 3 illustrates the cross-sectional view of a wafer structure W2, which includes a substrate 50 and an oxide layer 51 formed on the substrate 50. The substrate 50 may be the same as or similar to the substrate 40, thus details are not repeated. The oxide layer 51 may be, e.g., a layer of silicon oxide formed on the substrate 50 using a suitable formation method, such as CVD or thermal oxidization.

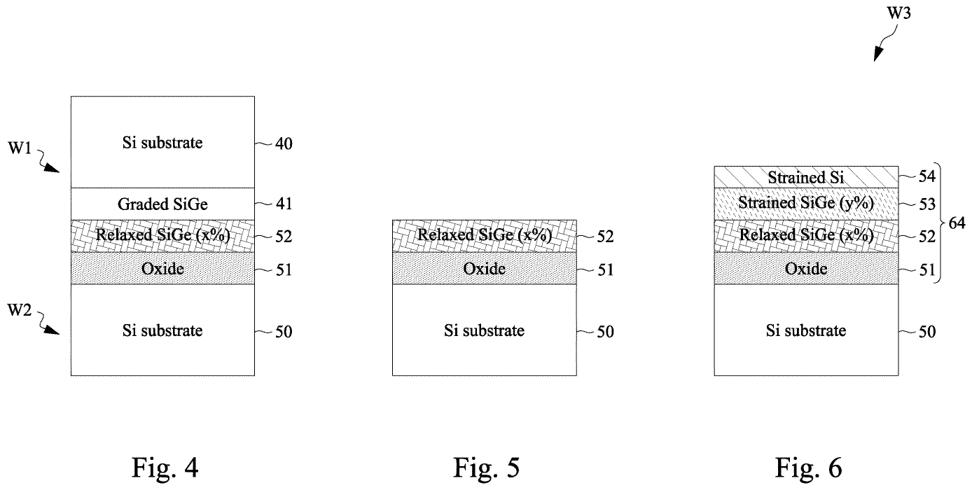

Next, in FIG. 4, the wafer structure W1 is flipped upside-down, and the relaxed silicon germanium layer 52 is bonded to the oxide layer 51 of the wafer structure W2. In the illustrated embodiment, direct bonding between the relaxed silicon germanium layer 52 and the oxide layer 51 is achieved without using an intermediate layer (e.g., an adhesive layer). The direct bonding may be achieved by the formation of covalent bonds between the relaxed silicon germanium layer 52 and the oxide layer 51.

Next, in FIG. 5, the substrate 40 and the graded silicon germanium layer 41 are removed, and the relaxed silicon germanium layer 52 is exposed. A suitable removal process, such as a grinding process, a planarization process (e.g., chemical mechanical planarization (CMP)), an etching process, combinations thereof, or the like, may be performed to remove the substrate 40 and the graded silicon germanium layer 41.

Next, in FIG. 6, a strained silicon germanium layer 53 and a strained silicon layer 54 are formed successively on the relaxed silicon germanium layer 52, e.g., by epitaxially growing a layer of silicon germanium and a layer of silicon on the relaxed silicon germanium layer 52. The strain in the strained silicon germanium layer 53 (or the strained silicon layer 54) may be produced by the mismatch in the lattice structures of the strained silicon germanium layer 53 (or the strained silicon layer 54) and the layer of material underlying it. The strains in the strained silicon germanium layer 53 and the strained silicon layer 54 may advantageously improve carrier mobility in the channel regions of the NSFET device formed.

In the illustrated embodiment, the strained silicon germanium layer 53 has a germanium concentration (e.g., atomic percentage) y % which is higher than the germanium concentration x % of the relaxed silicon germanium layer 52. In some embodiments, the germanium concentration y % is between about 40% and about 60%. The difference between the germanium concentration y % of the strained silicon germanium layer 53 and the germanium concentration x % of the relaxed silicon germanium layer 52 is between about 15% and about 35% (e.g., 15%<y %−x %<35%), in some embodiments. The relatively large difference (e.g., between 15% and 35%) between the germanium concentration y % and the germanium concentration x % generates the strain in the strained silicon germanium layer 53, and ensures a good etching selectivity between the strained silicon germanium layer 53 and the relaxed silicon germanium layer 52, such that in subsequent processing, the relaxed silicon germanium layer 52 can be removed by an etching process without substantially attacking the strained silicon germanium layer 53.

In the discussion herein, the oxide layer 51, the relaxed silicon germanium layer 52, the strained silicon germanium layer 53, and the strained silicon layer 54 in FIG. 6 may be collectively referred to as a multi-layer stack 64. The multi-layer stack 64 and the substrate 50 in FIG. 6 are collectively referred to as a wafer structure W3. FIG. 6 shows two layers (e.g., 52 and 53) of silicon germanium with different germanium concentrations and a layer (e.g., 54) of silicon in the multi-layer stack 64 as a non-limiting example. Other combinations of suitable materials, other numbers of layers of materials, and/or other arrangement of the layers of materials in the multi-layer stack 64 may also be used and are fully intended to be included within the scope of the present disclosure.

In subsequent processing, the relaxed silicon germanium layer 52 is removed in a sheet formation process. Therefore, the relaxed silicon germanium layer 52 may also be referred to as a sacrificial layer 52. As discussed above, the layers 53 and 54 of the multi-layer stack 64 may be formed of suitable semiconductor materials other than silicon germanium and silicon, and therefore, generic names, such as a first semiconductor material 53 and a second semiconductor material 54, may be used to refer to the materials of the layers 53 and 54, respectively. The layers 53 and 54 may also be referred to as a first semiconductor material layer 53 and a second semiconductor material layer 54, respectively. In subsequently processing, the first semiconductor material layer 53 and the second semiconductor material layer 54 are patterned and are used to form a first channel layer and a second channel layer of a channel region (e.g., a channel region having a dual-layered structure) of the NSFET device 100. Details are discussed hereinafter.

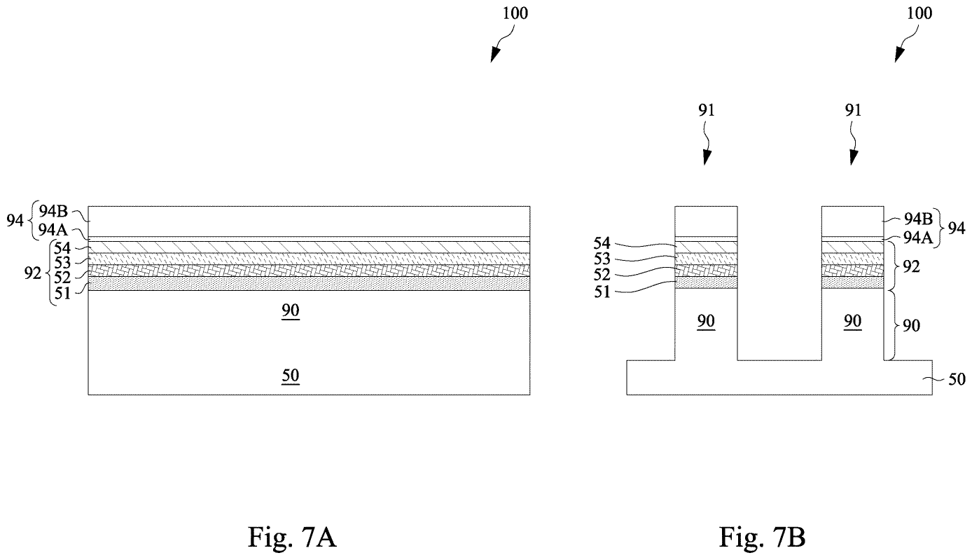

FIGS. 7A, 7B, 8A, 8B, 9A, 9B, 9C, 10A, 10B, 10C, 11A, 11B, 11C, 12A, 12B, 13A, 13B, 13C, 14A, 14B, 15A, and 15B illustrate cross-sectional views of the NSFET device 100 at subsequent stages of manufacturing, in accordance with an embodiment. FIGS. 7A, 8A, 9A, 10A, 11A, 12A, 13A, 14A, and 15A are cross-sectional views along cross-section A-A in FIG. 1. FIGS. 7B, 8B, 9B, 10B, 11B, 12B, 13B, 14B, and 15B are cross-sectional views along cross-section B-B in FIG. 1. FIGS. 9C, 10C, and 11C are cross-sectional views along cross-section C-C in FIG. 1. FIG. 13C illustrates a zoomed-in view of a portion of FIG. 13A. The number of fins and the number of gate structures illustrated in the figures are merely non-limiting examples, it should be appreciated that other numbers of fins and other numbers of gate structures may also be formed.

In FIGS. 7A and 7B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In an embodiment, a sacrificial layer is formed over a substrate and patterned using a photolithography process. Spacers are formed alongside the patterned sacrificial layer using a self-aligned process. The sacrificial layer is then removed, and the remaining spacers are then used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned portion of the substrate 50 forms the fins 90, as illustrated in FIGS. 7A and 7B. The unetched lower portion of the substrate 50 is referred to as substrate 50 in FIGS. 7A and 7B (and subsequent figures). Therefore, in the illustrated embodiment, the layer stack 92 includes the same layers of materials (e.g., 51, 52, 53, and 54) as the multi-layer stack 64, and the fin 90 is formed of a same material (e.g., silicon) as the substrate 50.

The fins 90 and the layer stacks 92 in FIG. 7B are illustrated to have substantially perpendicular sidewalls (e.g. perpendicular to the major upper surface of the substrate 50). The shapes of the fins 90 and the layer stacks 92 illustrated in FIG. 7B are merely non-limiting examples. The fins 90 and the layer stacks 92 may have sloped sidewalls (e.g., having trapezoidal cross-sections). The sloped sidewalls may be formed due to the properties of the anisotropic etching process used to form the fins 90 and the layer stacks 92. For example, the etching capability of the anisotropic etching process may decrease along the downward vertical direction of FIG. 7B, which may result in the sloped sidewalls for the fins 90 and the layer stacks 92.

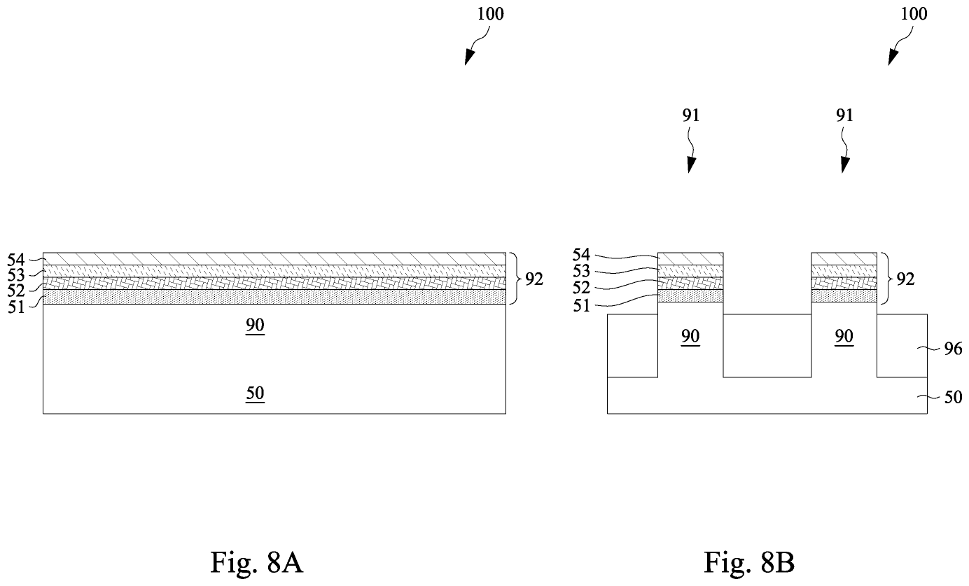

Next, in FIGS. 8A and 8B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. The removal process also removes the mask 94, in the illustrated embodiment. In some embodiments, a planarization process such as a CMP process, an etch back process, combinations thereof, or the like, may be utilized. The planarization process exposes the layer stacks 92 such that top surfaces of the layer stacks 92 and the insulation material are level after the planarization process is completed. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than other materials, such as the materials of the fin 90 and the layer stack 92). For example, a chemical oxide removal with a suitable etchant such as dilute hydrofluoric (dHF) acid may be used.

Next, in FIGS. 9A-9C, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by CMP. The dummy gate layer may be a conductive material and may be selected from a group including amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gates 102 and the dummy gate dielectrics 97 are collectively referred to as dummy gate structures 101.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

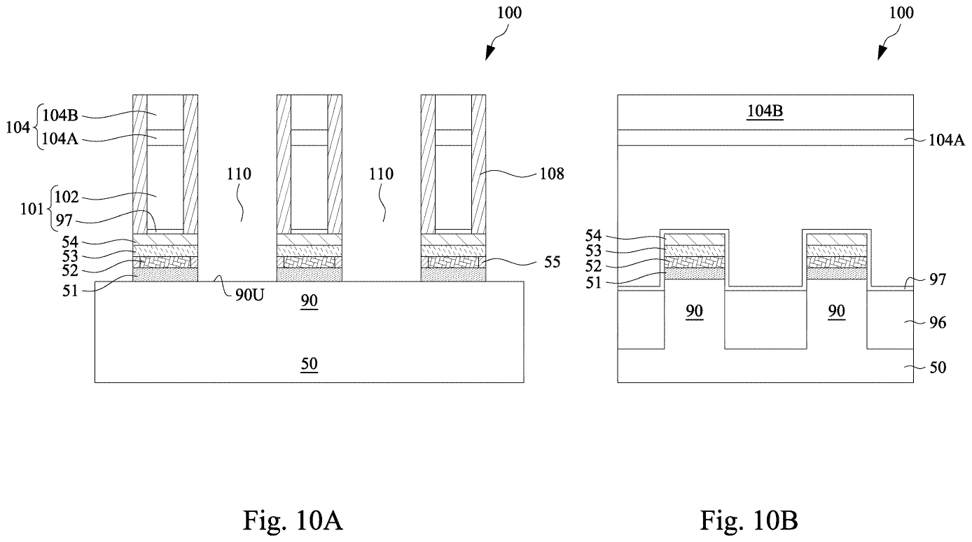

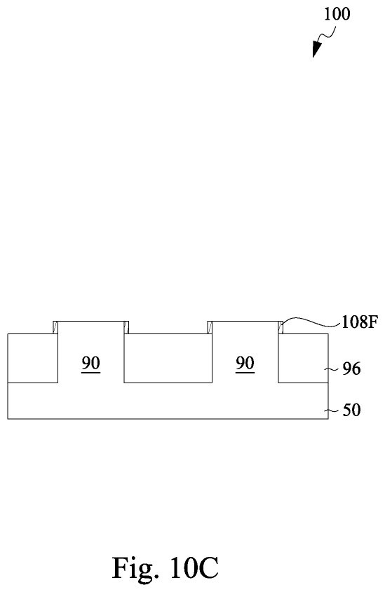

FIGS. 9B and 9C illustrate cross-sectional views of the NSFET device 100 in FIG. 9A along cross-sections E-E and F-F in FIG. 9A, respectively. The cross-sections E-E and F-F correspond to cross-sections B-B and C-C in FIG. 1, respectively. Unless otherwise specified, subsequent figures having reference numerals with alphabets A, B and C (e.g., FIGS. 10A, 10B, and 10C) illustrate cross-sectional views along the same cross-sections as FIGS. 9A, 9B, and 9C, respectively.

Next, in FIGS. 10A-10C, the gate spacer layer 108 is etched by an anisotropic etching process to form gate spacers 108. The anisotropic etching process may remove horizontal portions of the gate spacer layer 108 (e.g., portions over the STI regions 96 and the dummy gates structures 101), with remaining vertical portions of the gate spacer layer 108 (e.g., portions along sidewalls of the dummy gate structures 101) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, openings 110 (which may also be referred to as recesses, or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask.

After the openings 110 are formed, a selective etching process is performed to recess end portions of the sacrificial layer 52 exposed by the openings 110 without substantially attacking the first semiconductor material 53 and the second semiconductor material 54. After the selective etching process, recesses (also referred to as sidewall recesses) are formed in the sacrificial layer 52 at locations where the removed end portions used to be.

Next, an inner spacer layer is formed (e.g., conformally) in the openings 110 to line sidewalls and bottoms of the openings 110. The inner spacer layer also fills the sidewall recesses of the sacrificial layer 52 formed by the previous selective etching process. The inner spacer layer may be a suitable dielectric material, such as silicon carbonitride (SiCN), silicon oxycarbonitride (SiOCN), or the like, and may be formed by a suitable deposition method such as PVD, CVD, atomic layer deposition (ALD), or the like. Next, an etching process, such as an anisotropic etching process, is performed to remove portions of the inner spacer layer disposed outside the sidewall recesses of the sacrificial layer 52. The remaining portions of the inner spacer layer (e.g., portions disposed inside the sidewall recesses of the sacrificial layer 52) form inner spacers 55. As illustrated in FIG. 10A, the openings 110 expose sidewalls of the first semiconductor material 53 and the second semiconductor material 54, and expose upper surfaces 90U of the fins 90 at the bottoms of the openings 110.

In the example of FIG. 10C, portions of the gate spacer layer 108 disposed on the upper surface of the STI regions 96 between neighboring fins 90 are completely removed by the anisotropic etching process used for forming the gate spacers 108. Remaining portions of the gate spacer layer 108 along the sidewalls of the fins 90 form fin spacers 108F.

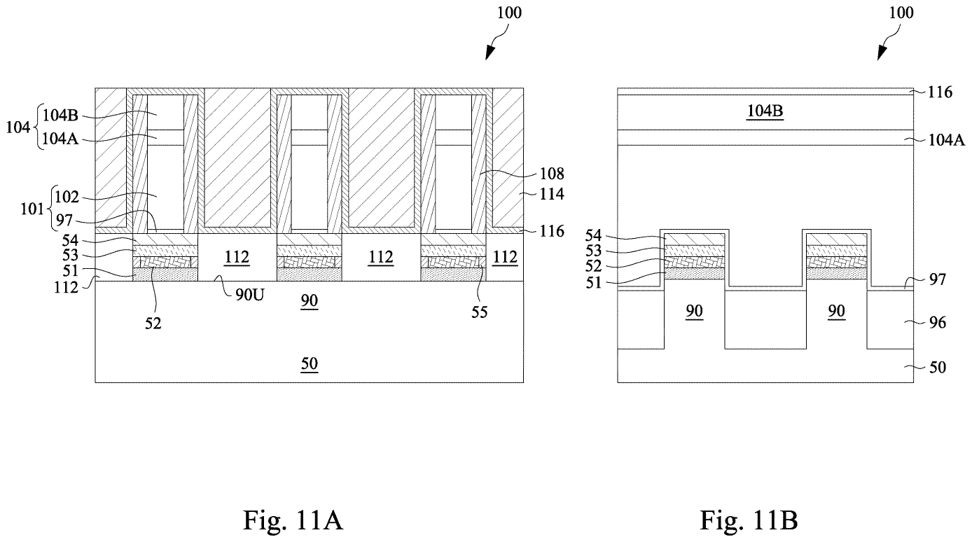

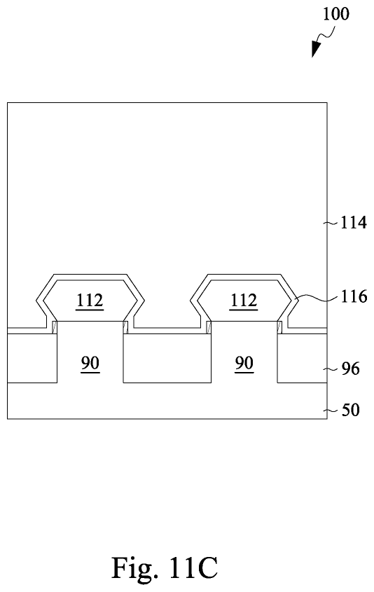

Next, in FIGS. 11A-11C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed replacement gate structures of the resulting NSFET device.

The epitaxial source/drain regions 112 are epitaxially grown in the openings 110, in some embodiments. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with a dopant (e.g., n-type impurities or p-type impurities), similar to the process previously discussed for forming lightly-doped source/drain regions, followed by an anneal. The source/drain regions may have an impurity concentration (may also be referred to as a dopant concentration) of between about 1E19/cm³ and about 1E21/cm³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 11C) after the epitaxy process is completed. In other embodiments, these facets cause adjacent epitaxial source/drain regions 112 to merge together.

Next, a contact etch stop layer (CESL) 116 is formed (e.g., conformally) over the source/drain regions 112 and over the dummy gate structures 101, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used.

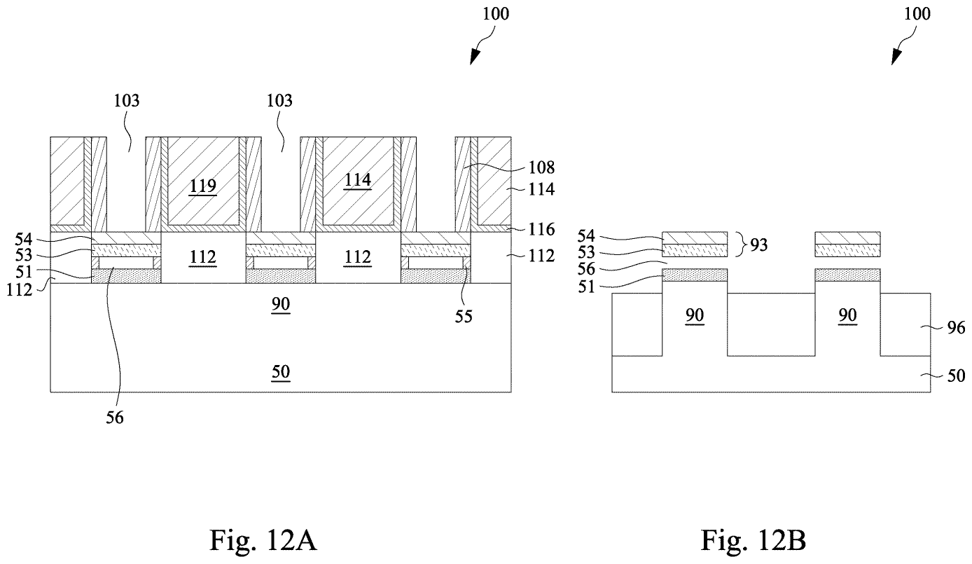

Next, in FIGS. 12A and 12B, the dummy gates 102 and the dummy gate dielectrics 97 are removed. Note that for simplicity, the cross-sectional views along cross-section F-F illustrated in FIG. 9A are not illustrated for processing steps hereinafter, because such cross-sectional views are the same as or similar to FIG. 11C, or may be easily modified from FIG. 11C (e.g., by adding additional layers formed over the first ILD 114 in subsequent processing).

To remove the dummy gates 102, a planarization process, such as a CMP, is performed to level the top surfaces of the first ILD 114 and the CESL 116 with the top surfaces of the dummy gates 102 and the gate spacers 108. The planarization process may also remove the masks 104 (see FIG. 10A) on the dummy gates 102, and portions of the gate spacers 108 along sidewalls of the masks 104. After the planarization process, top surfaces of the dummy gates 102, the gate spacers 108, the CESL 116, and the first ILD 114 are level. Accordingly, the top surfaces of the dummy gates 102 are exposed through the first ILD 114.

Next, the dummy gates 102 are removed in an etching step(s), so that recesses 103 (also referred to as gate trenches) are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectrics 97 may be used as an etch stop layer when the dummy gates 102 are etched. The dummy gate dielectrics 97 may then be removed after the removal of the dummy gates 102. An etching process, such as an isotropic etching process, may be performed to remove the dummy gate dielectrics 97. As illustrated in FIGS. 12A and 12B, the recesses 103 expose the channel regions of the NSFET device 100. The channel regions are disposed between neighboring pairs of the epitaxial source/drain regions 112.

Next, the sacrificial layer 52 (e.g., portions exposed by the recesses 103) is removed to release the first semiconductor material 53 (e.g., SiGe) and the second semiconductor material 54 (e.g., Si), and this process is referred to as a sheet formation process. After the sacrificial layer 52 is removed, the first semiconductor material 53 and the second semiconductor material 54 (e.g., portions underlying the dummy gates 102 before the dummy gates 102 are removed) form nanostructures 53 and nanostructures 54, respectively. The nanostructures 53 and 54 may be collectively referred to as the channel regions 93 or the channel layers 93 of the NSFET device 100 formed. The nanostructures 53 and 54 may be nanosheets or nanowires, depending on, e.g., the dimensions (e.g., size and/or aspect ratio) of the nanostructures 53 and 54.

In the illustrated embodiment, after the removal of the sacrificial layer 52, the first semiconductor material 53 and the second semiconductor material 54 disposed under the dummy gate 102 form a first channel layer 53 (e.g., a nanostructure 53) and a second channel layer 54 (e.g., a nanostructure 54), respectively. Notably, the first channel layer 53 contacts (e.g. physically contacts) and extends along the respective second channel layer 54. In other words, each channel region 93 of the NSFET device 100 has a dual-channel structure (also referred to as a dual-layered structure), which includes two channel layers (e.g., 53 and 54) formed of two different semiconductor materials. During operation of the NSFET device 100, electrical current flows between source/drain regions 112 through the first channel layer 53 and the second channel layer 54.

As illustrated in FIGS. 12A and 12B, gaps 56 (e.g., empty spaces) are formed between the nanostructures 53/54 and the underlying oxide layer 51 by the removal of the sacrificial layer 52. In some embodiments, the sacrificial layer 52 is removed by a selective etching process using an etchant that is selective to (e.g., having a higher etch rate for) the sacrificial layer 52, such that the sacrificial layer 52 is removed without substantially attacking the first semiconductor material 53 and the second semiconductor material 54. In some embodiments, an isotropic etching process is performed to selectively remove the sacrificial layer 52. The isotropic etching process may be performed using an etchant comprising ammonium hydroxide, as an example.

Next, in FIGS. 13A and 13B, a gate dielectric material 120 and a gate electrode material 122 are formed in the recesses 103 to form replacement gate structures 123. The gate dielectric material 120 is deposited conformally in the recesses 103, such as on the top surfaces and the sidewalls of the semiconductor fins 90, and on sidewalls of the gate spacers 108. The gate dielectric material 120 may also be formed on the top surface of the first ILD 114. Notably, the gate dielectric material 120 is formed to wrap around the dual-layered channel regions 93. In accordance with some embodiments, the gate dielectric material 120 comprises silicon oxide, silicon nitride, or multilayers thereof. In some embodiments, the gate dielectric material 120 is formed of a high-K dielectric material, and in these embodiments, the gate dielectric material 120 may have a dielectric constant (also referred to as K value) greater than about 7.0, and may include a metal oxide or a silicate of Hf, Al, Zr, La, Mg, Ba, Ti, or Pb, or combinations thereof. The formation methods of the gate dielectric material 120 may include Molecular-Beam Deposition (MBD), ALD, PECVD, and the like.

Next, the gate electrode material 122 is deposited over and around the gate dielectric material 120, and fills the remaining portions of the recesses 103. The gate electrode material 122 may include a metal-containing material such as Co, Ru, Al, W, TiN, TiO, TaN, TaC, combinations thereof, or multi-layers thereof. For example, although a single-layer gate electrode material 122 is illustrated, the gate electrode material 122 may comprise any number of liner layers (e.g., diffusion barrier layers), any number of work function tuning layers, and a fill material (e.g., a fill metal, an electrically conductive material). After the gate electrode material 122 is formed, a planarization process, such as a CMP, may be performed to remove excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120 of the replacement gate structures 123, respectively. Each gate electrode 122 and the corresponding gate dielectric layer 120 may be collectively referred to as a gate stack, a replacement gate structure, a metal gate structure, or a gate structure. Each replacement gate structure 123 extends around the respective nanostructures 53 and 54.

FIG. 13C illustrates a zoomed-in view of a portion 124 of the NSFET device 100 in FIG. 13A, in an embodiment. In the example of FIG. 13C, the upper surface 120U of a portion of the gate dielectric layer 120 filling the gap 56 (see FIGS. 12A and 12B) extends further from the substrate 50 than the lower surface 53L of the nanostructure 53 facing the substrate 50. In other words, there is a vertical offset H1 between the upper surface 120U of the portion of the gate dielectric layer 120 and the lower surface 53L of the nanostructure 53. The lower surface 120L of the portion of the gate dielectric layer 120 is level with the upper surface of the oxide layer 51 distal from the substrate. Recall that the sacrificial layer 52 is removed by a selective etching process. Since the sacrificial layer 52 (e.g., silicon germanium with a germanium concentration x %) and the first semiconductor material 53 (e.g., silicon germanium with a germanium concentration y %) both comprises silicon germanium, the selective etching process may still remove a minute amount of the first semiconductor material 53, thus resulting in the vertical offset H1.

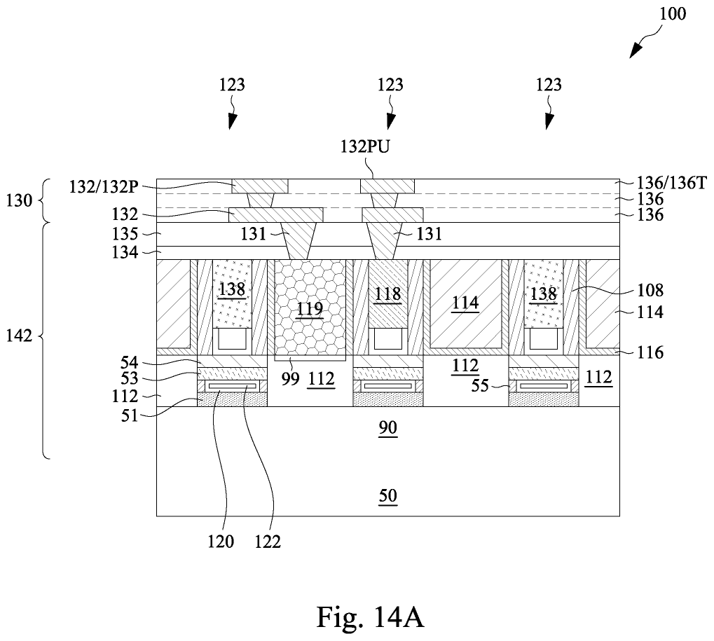

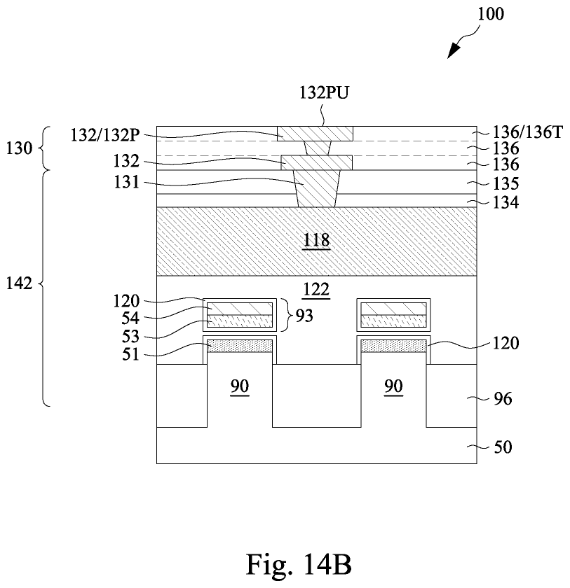

Next, in FIGS. 14A and 14B, gate masks 138 are formed over the replacement gate structures 123. The formation process of the gate masks 138 may include recessing replacement gate structures 123, filling the resulting recesses with a dielectric material such as silicon nitride, silicon carbonitride, silicon oxynitride, silicon oxycarbonitride, or the like, and performing a planarization process to remove excess portions of the dielectric material disposed over the first ILD 114. The remaining portions of the dielectric material form the gate masks 138.

Next, source/drain contact plugs 119 and gate contact plugs 118 are formed to electrically couple to the source/drain regions 112 and the replacement gate structures 123, respectively. In the illustrated embodiments, the source/drain contact plugs 119 and the gate contact plugs 118 are formed in a self-aligned manner, and fill the spaces between opposing sidewalls of the CESL 116 and spaces between opposing sidewalls of the gate spacers 108, respectively.

In some embodiments, one or more anisotropic etching processes are performed to remove portions of the first ILD 114 and portions of the CESL 116 that are disposed over the source/drain regions 112 to form source/drain contact openings that expose the source/drain regions 112. Similar, one or more anisotropic etching processes may be performed to remove the gate masks 138 to form gate contact openings that expose the replacement gate structures 123.

The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings. The number and the location of the source/drain contact plugs 119 and the gate contact plugs 118 illustrated in the figures are illustrative and non-limiting, as skilled artisans readily appreciate.

In the illustrated embodiments, silicide regions 99 are formed on the source/drain regions 112 before the source/drain contact openings are filled to form the source/drain contact plugs 119. In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 112, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

Next, an etch stop layer (ESL) 134 and a second ILD 135 are formed sequentially over, e.g., the first ILD 114, the replacement gate structures 123, and the gate spacers 108. The ESL 134 may include a dielectric material having a high etching selectivity from the etching of the second ILD 135, such as aluminum oxide, aluminum nitride, silicon oxycarbide, silicon nitride, silicon carbide, or the like, and may be formed using CVD, ALD, or the like. The second ILD 135 may be formed of PSG, BSG, BPSG, USG, or the like, which may be deposited by any suitable method, such as CVD, flowable CVD, PECVD, or the like.

Next, vias 131 are formed to extend through the second ILD 135 and the ESL 134, and to electrically couple to the source/drain contact plugs 119 and gate contact plugs 118. The vias 131 may be formed by forming via openings that extend through the second ILD 135 and the ESL 134, then filling the via openings with an electrically conductive material(s). The electrically conductive material(s) may be the same as or similar to those used for the source/drain contact plugs 119 or the gate contact plugs 118, thus details are not repeated. In some embodiments, a liner layer (e.g., a diffusion barrier layer) may be formed along sidewalls of the via openings before the electrically conductive material(s) fills the via openings. The liner layer may be titanium, tantalum, titanium nitride, tantalum nitride, or the like, and may be formed using any suitable formation methods, such as CVD, ALD, or the like.

In FIGS. 14A and 14B, the layers of the NSFET device 100 disposed between upper portions of the fins 90 and the second ILD 135 are collectively referred to as the device layer 142 of the NSFET device 100.

Still referring to FIGS. 14A and 14B, next, a front-side interconnect structure 130 is formed on the device layer 142. The front-side interconnect structure 130 includes dielectric layers 136 and layers of conductive features 132 in the dielectric layers 136. The dielectric layers 136 may include a suitable dielectric material, such as silicon oxide, silicon nitride, a low-K dielectric material, combinations therefore, or the like, and may be formed by any suitable formation method, such as CVD, PECVD, ALD, combinations thereof, or the like. The conductive features 132 (e.g., electrically conductive features) may include metal lines and vias, which may be formed using, e.g., damascene processes. The conductive features 132 may include diffusion barriers and a metal-containing material (e.g., copper) over the diffusion barriers. The diffusion barriers (may also be referred to as liner layers) may be, e.g., Ta, Ti, TaN, TiN, or the like. The metal-containing material may be, e.g., Cu, Co, Ru, Mo, or the like. In some embodiments, conductive features 132P (e.g., bonding pads, or metal patterns) used for bonding with another semiconductor device are formed in a topmost dielectric layer 136T of the front-side interconnect structure 130. The conductive features 132P may also be referred to as bonding features or bonding structures.

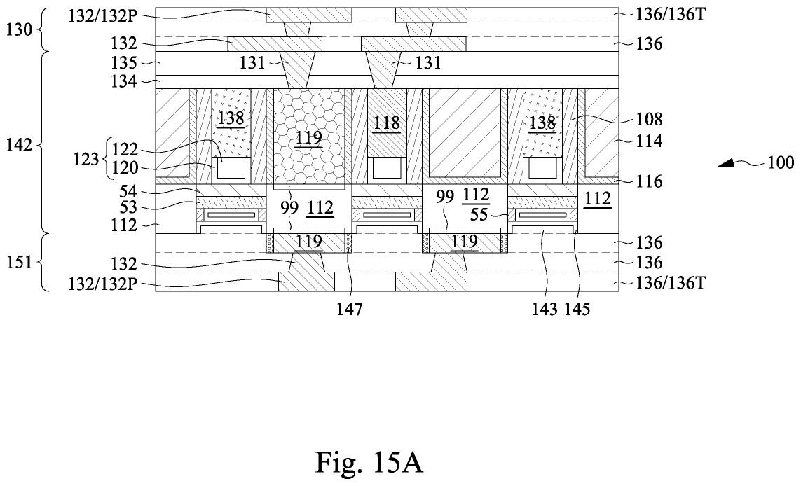

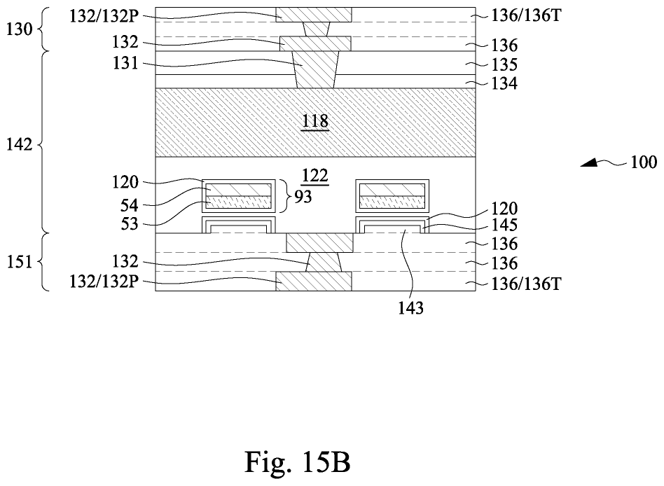

Next, in FIGS. 15A and 15B, a backside thinning process is performed, and a backside interconnect structure 151 is formed at an opposing side of the device layer 142 from the front-side interconnect structure 130. Details are discussed hereinafter.

In some embodiments, a thinning process (also referred to as backside thinning process) is performed from the backside of the substrate 50 to thin the substrate 50. The thinning process may be a grinding process, a CMP process, an etching process, combinations thereof, or the like. The thinning process may remove the substrate 50, the STI regions 96, and lower portions of the fins 90. In some embodiments, the thinning process is stopped when the source/drain regions 112 are exposed. Next, remaining portions of the fins 90 (e.g., top portions contacting the replacement gate structures 123) and the oxide layers 51 of the layer stacks 92 are removed (e.g., by one or more selective etching processes) to form recesses between, e.g., neighboring pairs of source/drain regions 112. An ESL 145 is formed to line sidewalls and bottoms of the recesses. The ESL 145 may be formed using a same or similar material and formation method as the CESL 116, thus details are not repeated. Next, a dielectric material 143 is formed on the ESL 145 and fills the recesses. The dielectric material 143 may be, e.g., SiO, SiN, or a low-K dielectric material formed using any suitable formation method. A planarization process, such as CMP, may be performed next to achieve a coplanar lower surface between the source/drain regions 112, the ESL 145, and the dielectric material 143. After the ESL 145 and the dielectric material 143 are formed, the layers of the NSFET device 100 disposed between the second ILD 135 and the lower surfaces of the source/drain regions 112 are collectively referred to as the device layer 142 of the NSFET device 100.

Next, the backside interconnect structure 151, which includes dielectric layers 136 and conductive features 132, is formed on the backside of the device layer 142. The backside interconnect structure 151 may include source/drain contact plugs 119 formed in the innermost dielectric layer 136 contacting the dielectric material 143. Silicide regions 99 are formed at the lower surfaces of the source/drain regions 112 before the source/drain contact plugs 119 are formed in the backside interconnect structure 151, in the illustrated embodiments. FIGS. 15A and 15B further illustrate a liner layer 147 (e.g., a diffusion barrier layer) around the source/drain contact plugs 119. The liner layer 147 may be formed of a suitable material such as titanium, tantalum, titanium nitride, tantalum nitride, or the like, and may be formed using any suitable formation methods, such as CVD, ALD, or the like. The backside interconnect structure 151 also includes conductive features 132P (e.g., bonding pads) embedded in an outermost dielectric layer 136T distal from the device layer 142.

FIGS. 16A and 16B illustrate cross-sectional views of an NSFET device 200, in an embodiment. The NSFET device 200 is similar to the NSFET device 100 and may be formed using a same or similar formation method. Notably, the NSFET device 200 also has channel regions 93 with a dual-layered structure. The source/drain regions 112 of the NSFET device 200 have a different conductivity type (e.g., n-type or p-type) from the source/drain regions 112 of the NSFET device 100, in some embodiments. For example, the source/drain regions 112 of the NSFET device 100 may have a first doping type (e.g., doped with a dopant of a first conductivity type, such as p-type), and the source/drain regions 112 of the NSFET device 200 may have a second doping type (e.g., doped with a dopant of a second conductivity type, such as n-type) different from the first doping type. In other words, one of the NSFET devices 100 and 200 may be formed using p-type NSFETs, and the other one of the NSFET devices 100 and 200 may be formed using n-type NSFETs. In other embodiments, the source/drain regions 112 of the NSFET device 100 and the source/drain regions 112 of the NSFET device 200 have a same doping type (e.g., both are doped with n-type or p-type dopant).

In the example of FIGS. 16A and 16B, the backside thinning process for removing the substrate 50 may be performed until the oxide layers 51 are removed. Therefore, the backside thinning process may also remove lower portions of the source/drain regions 112 of the NSFET device 200 and achieve a coplanar lower surface between the source/drain regions 112, the inner spacers 55, and the replacement gate structures 123. Next, the backside interconnect structure 151 is formed at the backside of the device layer 142 of the NSFET device 200.

Note that in the example of FIG. 16A, a source/drain contact plug 119A extends from the ESL 134, through the source/drain region 112, and through the backside interconnect structure 151. A lower surface 119L of the source/drain contact plug 119A is exposed at (e.g., flush with) a lower surface of the backside interconnect structure 151. Silicide regions 99 are formed along sidewalls of the source/drain region 112 facing the source/drain contact plug 119A. The source/drain contact plug 119A may be formed after the backside interconnect structure 151 is formed.

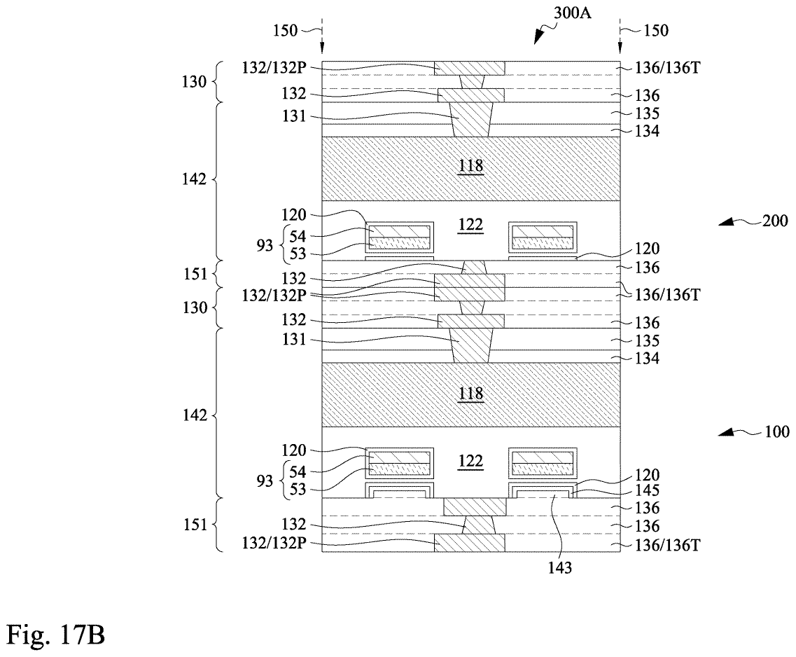

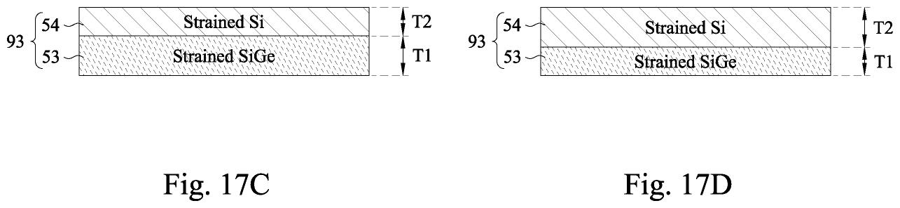

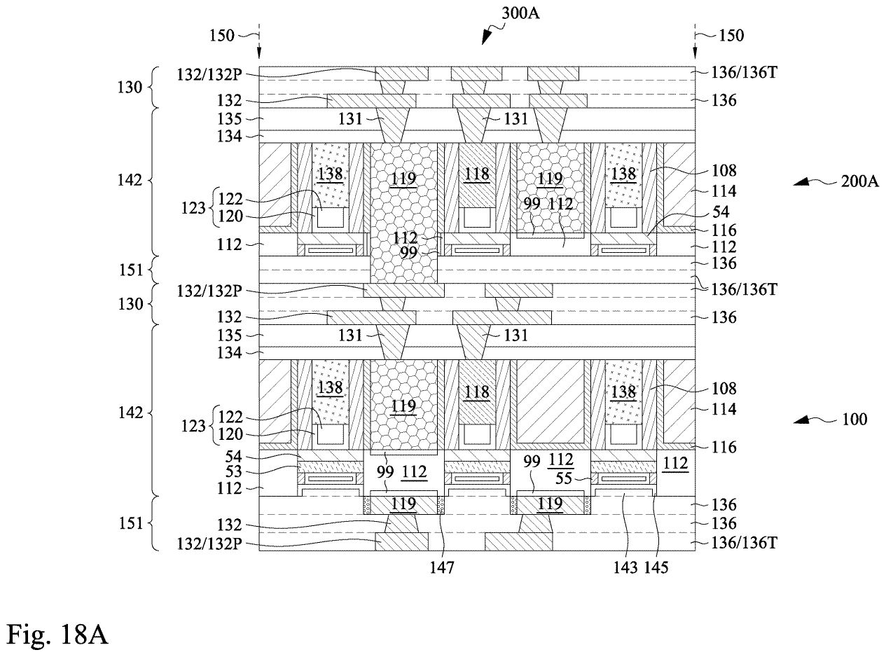

Next, in FIGS. 17A and 17B, the NSFET device 100 is bonded to the NSFET device 200 to form a CFET device 300. In the example of FIGS. 17A and 17B, the front-side interconnect structure 130 of the NSFET device 100 is bonded to the backside interconnect structure 151 of the NSFET device 200 to form the CFET device 300. This bonding scheme is also referred to as front-side to backside bonding.

In FIGS. 17A and 17B, the topmost dielectric layer 136T of the front-side interconnect structure 130 of the NSFET device 100 is bonded with the topmost dielectric layer 136T of the backside interconnect structure 151 of the NSFET device 200 through dielectric-to-dielectric bonding (also referred to as direct dielectric-to-dielectric bonding), and the conductive features 132P of the front-side interconnect structure 130 of the NSFET device 100 are bonded with respective conductive features of the backside interconnect structure 151 of the NSFET device 200 through metal-to-metal bonding (also referred to as direct metal-to-metal bonding). FIG. 17A illustrates metal-to-metal bonding between the conductive features 132P of the NSFET device 100 and the source/drain contact plug 119A of the NSFET device 200, and FIG. 17B illustrates metal-to-metal bonding between the conductive features 132P of the NSFET device 100 and a corresponding conductive features 132P of the NSFET device 200.

Dielectric-to-dielectric bonding and metal-to-metal bonding are bonding techniques that could be used in a direct bonding process to bond two semiconductor devices together without using an intermediate layer (e.g., solder or an adhesive layer). The direct bonding process uses dielectric-to-dielectric bonding and/or metal-to-metal bonding to achieve a robust and reliable connection at the interface of two devices. Metal-to-metal bonding involves aligning and applying sufficient pressure on metal surfaces, such as copper or aluminum surfaces, often accompanied by thermal treatment to facilitate atomic diffusion and interfacial adhesion without an intermediate layer (e.g., solder). Dielectric-to-dielectric bonding uses surfaces such as silicon dioxide or other insulating materials, which, when aligned under appropriate conditions (e.g., at an elevated temperature and/or with pressure applied at the surfaces), form bonds through forces such as Van der Waals force or covalent interactions. The direct bonding process is instrumental in creating high-density, low-resistance connections while reducing or minimizing thermal budgets.

FIG. 17C illustrates the first channel layer 53 and the second channel layer 54 of an n-type NSFET device (e.g., 100) in the CFET device 300, in an embodiment. In the illustrated example, the first channel layer 53 (e.g., strained silicon germanium) has a thickness T1, and the second channel layer 54 (e.g., strained silicon) has a thickness T2, where T1>T2. In other words, the first channel layer 53 (e.g., strained silicon germanium) is used as the main channel (e.g., with more current flowing through the first channel layer 53 than the second channel layer 54 during operation) of the dual-layered channel region 93.

FIG. 17D illustrates the first channel layer 53 and the second channel layer 54 of a p-type NSFET device (e.g., 200) in the CFET device 300, in an embodiment. In the illustrated example, the first channel layer 53 (e.g., strained silicon germanium) has a thickness T1, and the second channel layer 54 (e.g., strained silicon) has a thickness T2, where T2>T1. In other words, the second channel layer 54 (e.g., strained silicon) is used as the main channel of the dual-layered channel region 93.

In some embodiments, multiple NSFET devices 100 are formed on a first wafer (e.g., a substrate 50), and multiple NSFET devices 200 are formed on a second wafer (e.g., another substrate 50). After both wafers are bonded together, a wafer-on-wafer structure is formed that comprises multiple CFET devices 300. Next, a dicing process is performed along dicing regions indicated by the dashed lines 150 in FIGS. 17A and 17B to separate the wafer-on-wafer structure into individual (e.g., separate) CFET devices 300, where each of the CFET devices 300 includes an NSFET device 100 and an NSFET device 200 stacked vertically (e.g., bonded together). In some embodiments, the NSFET devices 100 and 200 in the CFET device 300 are of different conductivity types. In other embodiments, the NSFET devices 100 and 200 in the CFET device 300 are of the same conductivity type.

Advantages are achieved by using the dual-layered channel regions in the CFET device 300. The dual-layered channel region (e.g., comprising a strained silicon germanium (SiGe) layer and a strained silicon (Si) layer) achieves enhanced carrier mobility through band energy alignment. The strained SiGe channel provides improved hole mobility for p-type metal-oxide-semiconductor (PMOS) operation, while the strained Si channel delivers enhanced electron mobility for n-type metal-oxide-semiconductor (NMOS) operation. The engineered band alignment between the SiGe and Si layers creates optimized energy barriers and carrier confinement regions, resulting in reduced carrier scattering and lower effective mass for both electrons and holes. This complementary enhancement of carrier transport properties in the dual channel structure enables improved switching speeds, lower power consumption, and overall better device performance in the resulting semiconductor device. The strategic combination of these strained materials with their aligned energy bands provides simultaneous optimization of both electron and hole mobility within the same device structure, thereby achieving superior CMOS performance characteristics.

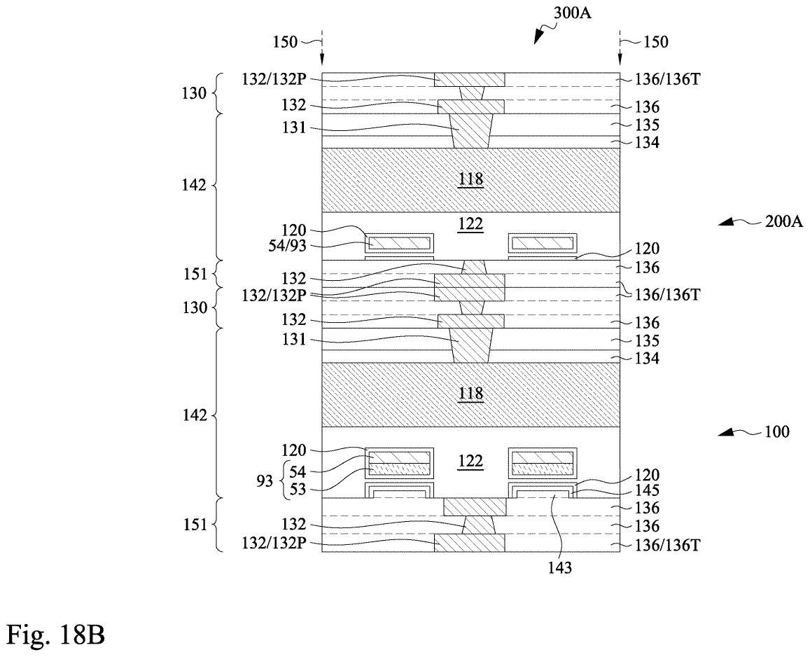

FIGS. 18A and 18B illustrate cross-sectional views of a CFET device 300A, in accordance with another embodiment. The CFET device 300A is similar to the CFET device 300, and is formed by bonding the NSFET device 100 to an NSFET device 200A. The NSFET device 200A is similar to the NSFET device 200, but the channel regions of the NSFET device 200A include nanostructures 54 but not nanostructures 53. In other words, the channel regions of the NSFET device 200A do not have the dual-layered structure of the channel regions of the NSFET device 200.

To form the NSFET device 200A, the first semiconductor material 53 in FIG. 6 is omitted during the formation of the wafer structure W3. The wafer structure W3 (with the first semiconductor material 53 omitted) is then processed following the same or similar processing steps for forming the NSFET device 200. After the sacrificial layer 52 is removed in the sheet formation process, the second semiconductor material 54 remains and forms nanostructures 54 (e.g., channel regions) of the NSFET device 200A. Skilled artisans, upon reading the disclosure herein, should readily be able to modify the processing steps for the NSFET device 200 to form the NSFET device 200A, thus details are not discussed here.

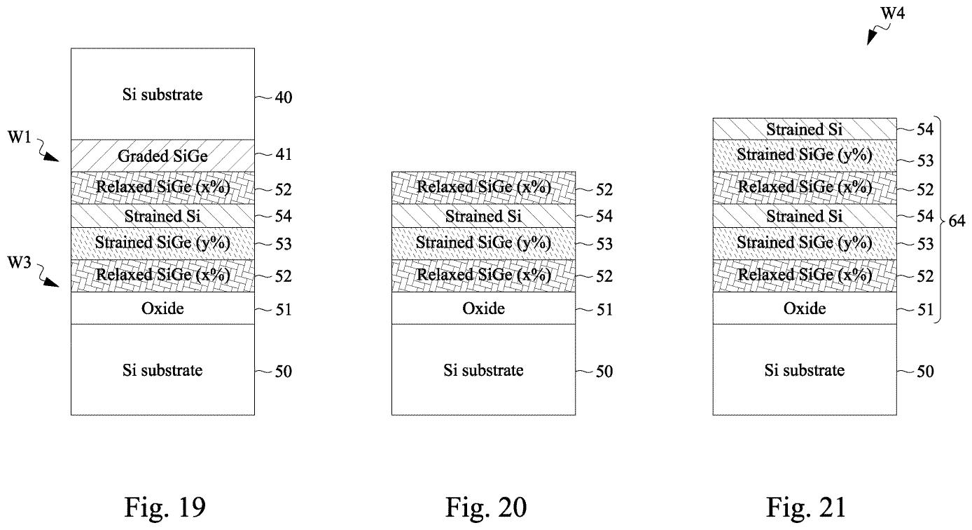

FIGS. 19, 20, 21, 22A, and 22B illustrate cross-sectional views of a CFET device 300B at various stages of manufacturing, in accordance with another embodiment.

In FIG. 19, a wafer structure W3 of FIG. 6 is bonded to a wafer structure W1 of FIG. 2B. In particular, the second semiconductor material layer 54 of the wafer structure W3 is bonded to the sacrificial layer 52 of the wafer structure W1 through direct bonding. Next, in FIG. 20, the substrate 40 and the graded silicon germanium layer 41 are removed, and the sacrificial layer 52 is exposed. Next, in FIG. 21, a wafer structure W4 is formed by forming another layer of the first semiconductor material 53 and another layer of the second semiconductor material 54 successively on the exposed sacrificial layer 52, e.g., using suitable epitaxial formation methods. Note that in the multi-layer stack 64 of the wafer structure W4, the sacrificial layer 52, the first semiconductor material layer 53, and the second semiconductor material layer 54 are duplicated. This allows two dual-layered channel regions 93 to be formed by patterning the multi-layer stack 64 and removing the sacrificial layers 52. In other words, each of the transistor formed using the wafer structure W4 has two dual-layered channel regions 93 stacked vertically, where each channel region 93 includes a first channel layer 53 and a second channel layer 54.

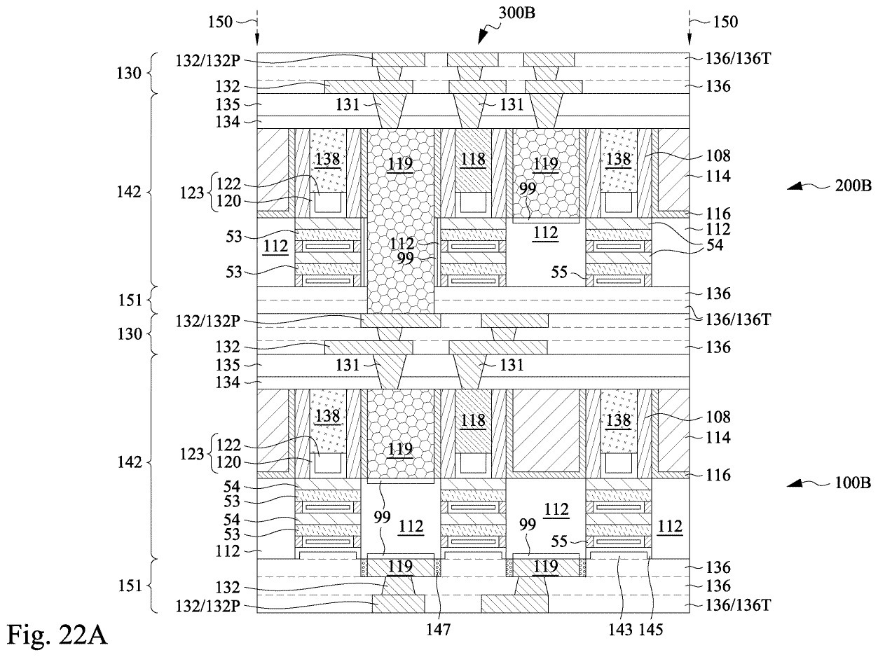

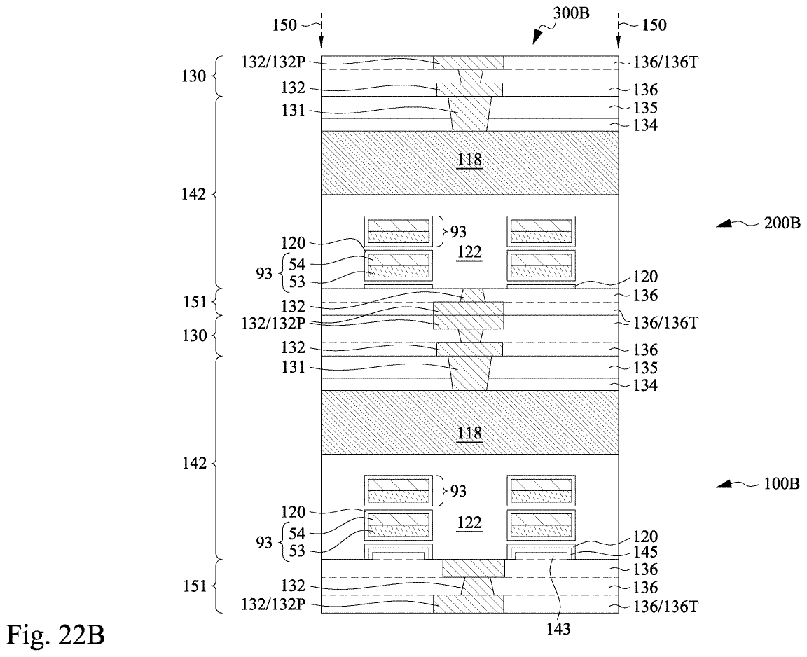

Next, an NSFET device 100B (or an NSFET device 200B) is formed by performing the same or similar processing steps for the NSFET device 100 (or the NSFET device 200) for the wafer structure W4. The NSFET device 100B is then bonded to the NSFET device 200B to form the CFET device 300B. As illustrated in FIGS. 22A and 22B, the channel regions of the NSFET devices 100B (or 200B) between adjacent source/drain regions 112 include two dual-layered channel regions 93 stacked vertically.

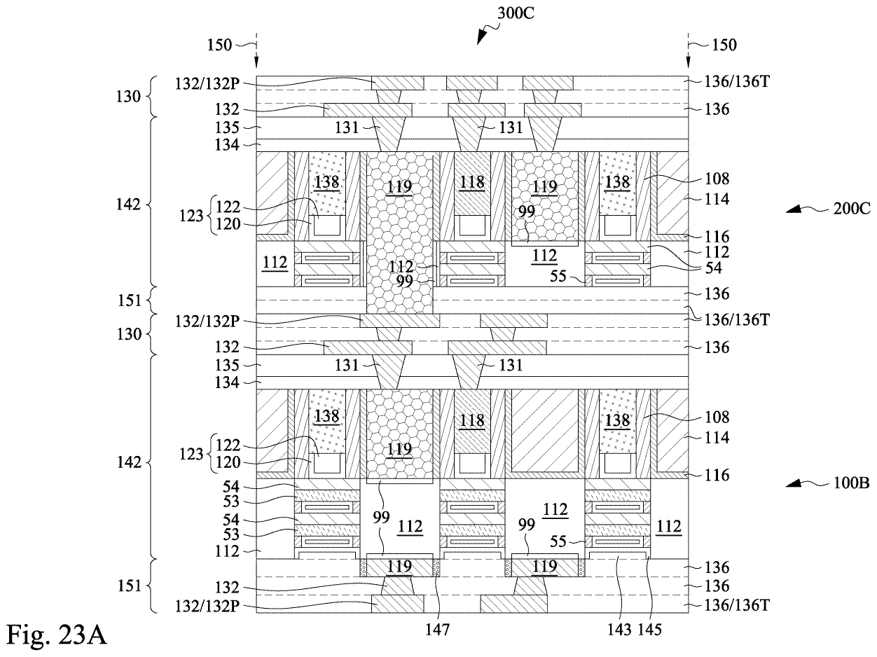

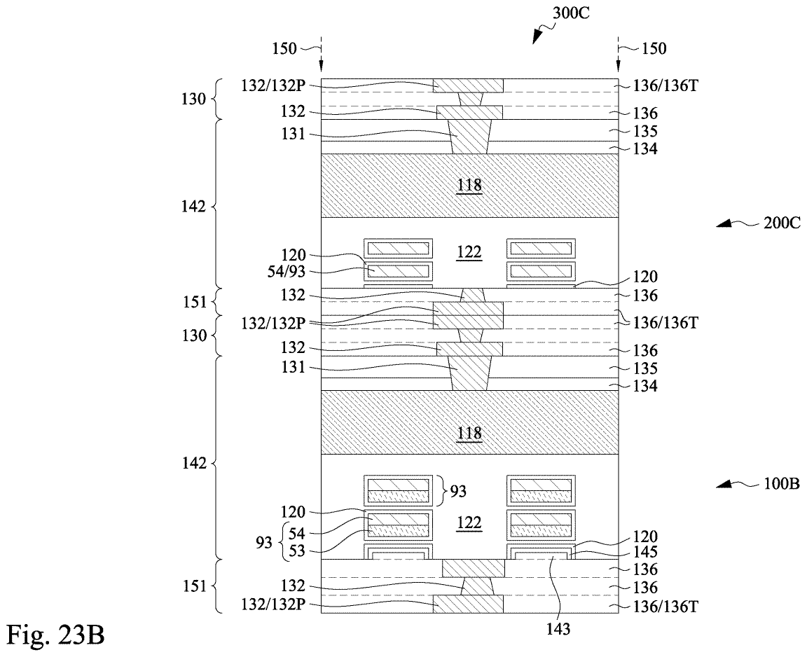

FIGS. 23A and 23B illustrate cross-sectional views of a CFET device 300C, in accordance with another embodiment. The CFET device 300C is formed by bonding the NSFET device 100B to an NSFET device 200C. The NSFET device 200C is similar to the NSFET device 200B, but the channel regions of the NSFET device 200C do not have the dual-layered structure, and instead, only have nanostructures 54 as the channel regions. The NSFET device 200C may be formed by: forming a wafer structure similar to the wafer structure W4 of FIG. 21, but omitting the first semiconductor material layers 53; and performing the same or similar processing steps for forming the NSFET device 200 on the wafer structure (with first semiconductor material layers 53 omitted) formed above. Details are not discussed here.

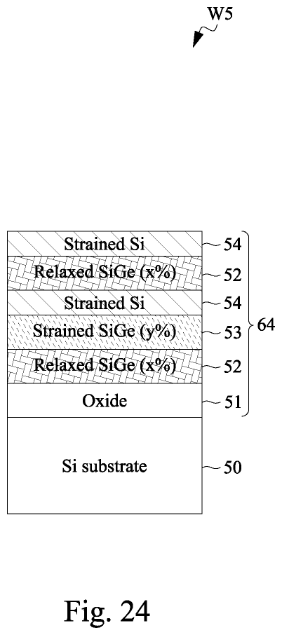

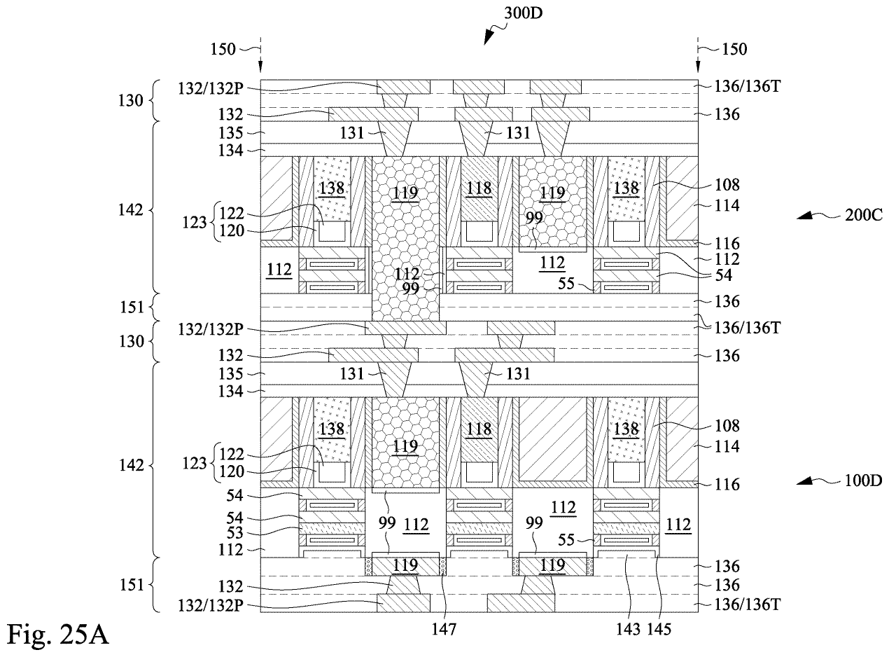

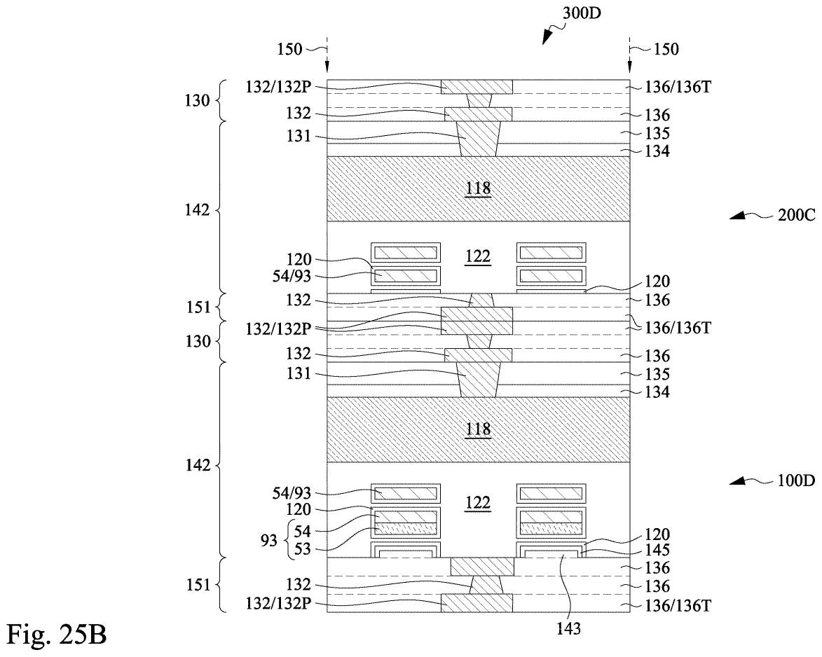

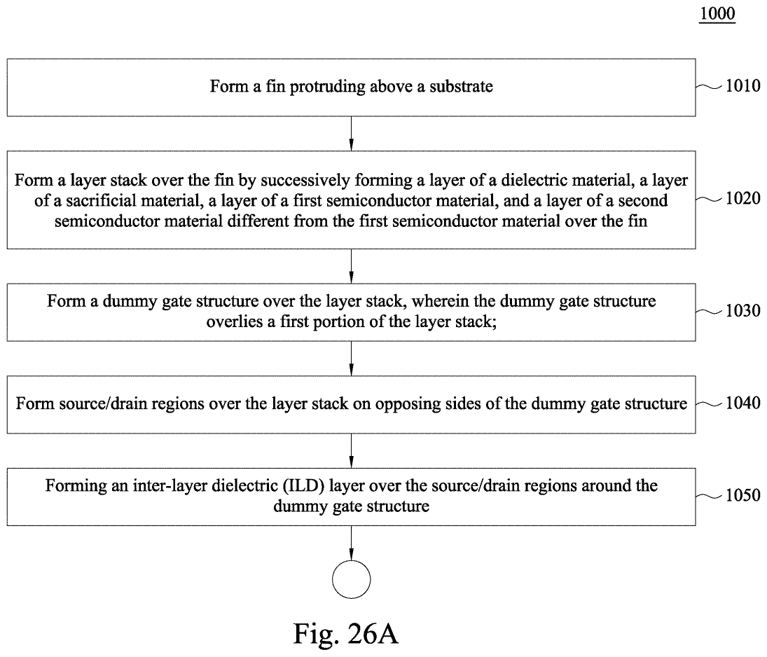

FIGS. 24, 25A, and 25B illustrate cross-sectional views of a CFET device 300D at various stages of manufacturing, in accordance with yet another embodiment.

In FIG. 24, a wafer structure W5 is formed by forming another sacrificial layer 52 and another layer of the second semiconductor material 54 successively on the wafer structure W3 of FIG. 6 using, e.g., suitable epitaxial formation methods. Next, an NSFET device 100D is formed by performing the same or similar processing steps for forming the NSFET device 100.

Next, in FIGS. 25A and 25B, the NSFET device 100D is bonded to the NSFET device 200C to form the CFET device 300D. The NSFET device 200C is the same as the NSFET device 200C in FIGS. 23A and 23B. The channel regions 93 of the NSFET device 200C are single-layered channel regions, where each channel region 93 includes a second channel layer 54. Note that the channel regions of the NSFET device 100D disposed between adjacent source/drain regions 112 include a dual-layered channel region 93 (that includes a first channel layer 53 and a second channel layer 54) and a single-layered channel region 93 (that includes a second channel layer 54) over the dual-layered channel region 93.

Variations and modification to the disclosed embodiments are possible, and are fully intended to be included within the scope of the present disclosure. For example, beside the front-side to backside bonding scheme illustrated in the various embodiments, other bonding schemes, such as front-side to front-side bonding, may also be used to bond the interconnect structures of two NSFET devices together to form a CFET device. As another example, the number of vertically stacked channel regions 93 in the transistor of the NSFET device in the disclosed embodiments is one or two, with the understanding that more than two vertically stacked channel regions may be used for each transistor formed.

Advantages are achieved by the disclosed embodiments. The CFET devices utilize dual-layered channel regions comprising strained silicon germanium (SiGe) and strained silicon (Si) layers. As a result, increased strain to the channel regions is achieved, which in turn increases the carrier mobility in the channel regions. In addition, the dual-layered channel regions achieve enhanced carrier mobility through band energy alignment. The engineered band alignment between the SiGe and Si layers creates optimized energy barriers and carrier confinement regions, resulting in reduced carrier scattering and lower effective mass for both electrons and holes. This complementary enhancement of carrier transport properties in the dual channel structure enables improved switching speeds, lower power consumption, and overall better device performance in the resulting semiconductor device. The strategic combination of these strained materials with their aligned energy bands provides simultaneous optimization of both electron and hole mobility within the same device structure, thereby achieving superior CMOS performance characteristics.

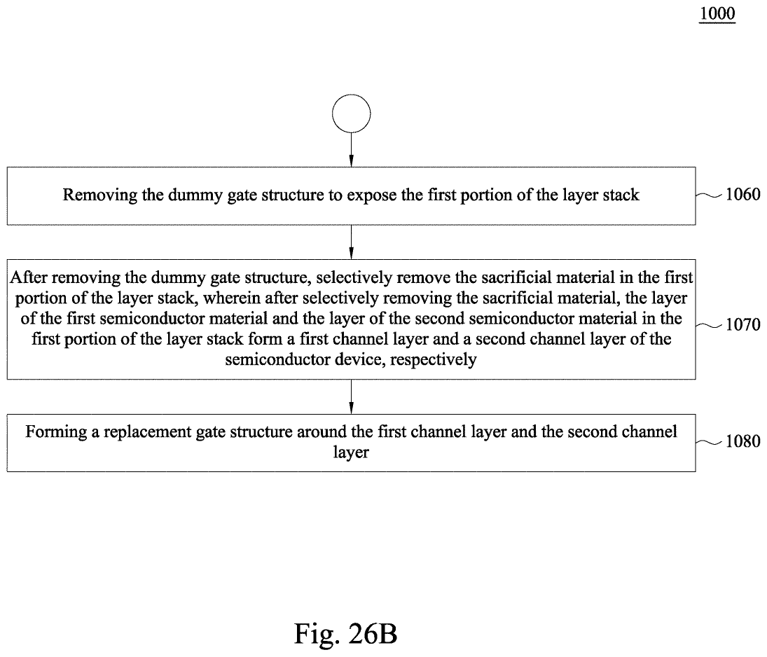

FIGS. 26A and 26B together illustrate a flow chart of a method 1000 of forming a semiconductor device, in accordance with some embodiments. It should be understood that the embodiment method shown in FIGS. 26A and 26B is merely an example of many possible embodiment methods. One of ordinary skill in the art would recognize many variations, alternatives, and modifications. For example, various steps as illustrated in FIGS. 26A and 26B may be added, removed, replaced, rearranged, or repeated.

Referring to FIGS. 26A and 26B, at block 1010, a fin is formed protruding above a substrate. At block 1020, a layer stack is formed over the fin by successively forming a layer of a dielectric material, a layer of a sacrificial material, a layer of a first semiconductor material, and a layer of a second semiconductor material different from the first semiconductor material over the fin. At block 1030, a dummy gate structure is formed over the layer stack, wherein the dummy gate structure overlies a first portion of the layer stack. At block 1040, source/drain regions are formed over the layer stack on opposing sides of the dummy gate structure. At block 1050, an inter-layer dielectric (ILD) layer is formed over the source/drain regions around the dummy gate structure. At block 1060, the dummy gate structure is removed to expose the first portion of the layer stack. At block 1070, after removing the dummy gate structure, the sacrificial material in the first portion of the layer stack is selectively removed, wherein after selectively removing the sacrificial material, the layer of the first semiconductor material and the layer of the second semiconductor material in the first portion of the layer stack form a first channel layer and a second channel layer of the semiconductor device, respectively. At block 1080, a replacement gate structure is formed around the first channel layer and the second channel layer.

In an embodiment, a method of forming a semiconductor device includes forming a first nanostructure field-effect transistor (NSFET) device, wherein forming the first NSFET device includes: forming a first fin structure protruding above a first substrate, wherein the first fin structure comprises a first fin and a first layer stack over the first fin, wherein the first layer stack comprises a layer of a dielectric material, a layer of a sacrificial material, a layer of a first semiconductor material, and a layer of a second semiconductor material formed successively over the first fin, wherein the second semiconductor material is different from the first semiconductor material; forming a first dummy gate structure over the first fin structure; forming first source/drain regions over the first fin structure on opposing sides of the first dummy gate structure; removing the first dummy gate structure to expose a first portion of the first layer stack; selectively removing the sacrificial material in the first portion of the first layer stack, wherein after selectively removing the sacrificial material in the first portion of the first layer stack, the layer of the first semiconductor material and the layer of the second semiconductor material in the first portion of the first layer stack form a first channel layer and a second channel layer of the first NSFET device, respectively; and forming a first replacement gate structure around the first channel layer and the second channel layer. In an embodiment, the dielectric material in the first layer stack is silicon oxide, wherein the sacrificial material in the first layer stack is silicon germanium with a first concentration of germanium, wherein the first semiconductor material in the first layer stack is silicon germanium with a second concentration of germanium higher than the first concentration, wherein the second semiconductor material in the first layer stack is silicon. In an embodiment, the first NSFET device is an n-type device, wherein the layer of the second semiconductor material in the first layer stack is formed to be thinner than the layer of the first semiconductor material in the first layer stack. In an embodiment, the first NSFET device is a p-type device, wherein the layer of the second semiconductor material in the first layer stack is formed to be thicker than the layer of the first semiconductor material in the first layer stack. In an embodiment, the first layer stack further comprises another layer of the sacrificial material and another layer of the second semiconductor material formed successively over the layer of the second semiconductor material, wherein after selectively removing the sacrificial material in the first portion of the first layer stack, the another layer of the second semiconductor material in the first portion of the first layer stack forms a third channel layer of the first NSFET device. In an embodiment, the second channel layer is in contact with the first channel layer, wherein the second channel layer is spaced apart from the third channel layer. In an embodiment, upper sides of the first source/drain regions face away from the first substrate, wherein forming the first NSFET device further comprises: forming a first interconnect structure at the upper sides of the first source/drain regions, wherein the first interconnect structure is electrically coupled to the first source/drain regions. In an embodiment, lower sides of the first source/drain regions face the first substrate, wherein forming the first NSFET device further comprises: removing the first substrate after forming the first interconnect structure; after removing the first substrate, removing the dielectric material of the first layer stack, wherein the lower sides of the first source/drain regions are exposed after removing the dielectric material; and forming a second interconnect structure at the lower sides of the first source/drain regions, wherein the second interconnect structure is electrically coupled to the first source/drain regions. In an embodiment, the method further comprises bonding the first interconnect structure or the second interconnect structure of the first NSFET device to a third interconnect structure of a second NSFET device to form a complementary field-effect transistor (CFET) device. In an embodiment, the second NSFET device is pre-formed before being bonded to the first NSFET device, wherein the bonding comprises bonding the first interconnect structure or the second interconnect structure to the third interconnect structure through dielectric-to-dielectric bonding and metal-to-metal bonding without using an intermediate layer. In an embodiment, the method further comprises forming the second NSFET device before the bonding, wherein forming the second NSFET device comprises: forming a second fin structure protruding above a second substrate, wherein the second fin structure comprises a second fin and a second layer stack over the second fin, wherein the second layer stack has a same structure as the first layer stack; forming a second dummy gate structure over the second fin structure; forming second source/drain regions over the second fin structure on opposing sides of the second dummy gate structure; removing the second dummy gate structure to expose a second portion of the second layer stack; selectively removing the sacrificial material in the second portion of the second layer stack, wherein after selectively removing the sacrificial material in the second portion of the second layer stack, the layer of the first semiconductor material and the layer of the second semiconductor material in the second portion of the second layer stack form a third channel layer and a fourth channel layer of the second NSFET device, respectively; forming a second replacement gate structure around the third channel layer and the fourth channel layer; and forming the third interconnect structure over and electrically coupled to the second source/drain regions. In an embodiment, the method further comprises forming the second NSFET device before the bonding, wherein forming the second NSFET device comprises: forming a second fin structure protruding above a second substrate, wherein the second fin structure comprises a second fin and a second layer stack over the second fin, wherein the second layer stack comprises a layer of the dielectric material, a layer of the sacrificial material, and a layer of the second semiconductor material formed successively over the second fin; forming a second dummy gate structure over the second fin structure; forming second source/drain regions over the second fin structure on opposing sides of the second dummy gate structure; removing the second dummy gate structure to expose a second portion of the second layer stack; selectively removing the sacrificial material in the second portion of the second layer stack, wherein after selectively removing the sacrificial material in the second portion of the second layer stack, the layer of the second semiconductor material in the second portion of the second layer stack forms a third channel layer of the second NSFET device; forming a second replacement gate structure around the third channel layer; and forming the third interconnect structure over and electrically coupled to the second source/drain regions.

In an embodiment, a method of forming a semiconductor device includes: forming a fin protruding above a substrate; forming a layer stack over the fin by successively forming a layer of a dielectric material, a layer of a sacrificial material, a layer of a first semiconductor material, and a layer of a second semiconductor material different from the first semiconductor material over the fin; forming a dummy gate structure over the layer stack, wherein the dummy gate structure overlies a first portion of the layer stack; forming source/drain regions over the layer stack on opposing sides of the dummy gate structure; forming an inter-layer dielectric (ILD) layer over the source/drain regions around the dummy gate structure; removing the dummy gate structure to expose the first portion of the layer stack; after removing the dummy gate structure, selectively removing the sacrificial material in the first portion of the layer stack, wherein after selectively removing the sacrificial material, the layer of the first semiconductor material and the layer of the second semiconductor material in the first portion of the layer stack form a first channel layer and a second channel layer of the semiconductor device, respectively; and forming a replacement gate structure around the first channel layer and the second channel layer. In an embodiment, the first channel layer contacts the second channel layer. In an embodiment, the source/drain regions are n-type source/drain regions, wherein the first semiconductor material in the layer stack is formed to be thicker than the second semiconductor material in the layer stack. In an embodiment, the source/drain regions are p-type source/drain regions, wherein the first semiconductor material in the layer stack is formed to be thinner than the second semiconductor material in the layer stack. In an embodiment, forming the layer stack further comprises successively forming another layer of the sacrificial material and another layer of the second semiconductor material over the layer of the second semiconductor material, wherein after selectively removing the sacrificial material in the first portion of the layer stack, the another layer of the second semiconductor material in the first portion of the layer stack forms a third channel layer of the semiconductor device, wherein the third channel layer is spaced apart from the second channel layer.

In an embodiment, a semiconductor device includes a first nanostructure field-effect transistor (NSFET) device, wherein the first NSFET device comprises: a first source/drain region and a second source/drain region; a first channel layer and a second channel layer that are disposed between the first source/drain region and the second source/drain region, wherein the first channel layer contacts the second channel layer, wherein the first channel layer is a layer of a first semiconductor material, and the second channel layer is a layer of a second semiconductor material different from the first semiconductor material; a first gate structure around the first channel layer and the second channel layer; and a first interconnect structure at a first side of the first source/drain region and electrically coupled to the first source/drain region. In an embodiment, the first NSFET device further comprises a third channel layer disposed between the first source/drain region and the second source/drain region, wherein the third channel layer is a layer of the second semiconductor material, wherein the third channel layer is spaced apart from the second channel layer. In an embodiment, the semiconductor device further includes a second NSFET device, wherein the second NSFET device comprises: a third source/drain region and a fourth source/drain region; a third channel layer and a fourth channel layer that are disposed between the third source/drain region and the fourth source/drain region, wherein the third channel layer contacts the fourth channel layer, wherein the third channel layer is a layer of the first semiconductor material, and the fourth channel layer is a layer of the second semiconductor material; a second gate structure around the third channel layer and the fourth channel layer; and a second interconnect structure at a second side of the third source/drain region and electrically coupled to the third source/drain region, wherein the second interconnect structure is bonded to the first interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first nanostructure field-effect transistor (NSFET) device comprising:
a first source/drain region and a second source/drain region;
a first channel layer and a second channel layer that are disposed between the first source/drain region and the second source/drain region, wherein the second channel layer extends along and contacts the first channel layer, wherein the first channel layer is a layer of a first semiconductor material, and the second channel layer is a layer of a second semiconductor material different from the first semiconductor material;
a first gate structure around the first channel layer and the second channel layer;
first gate spacers along opposing sidewalls of the first gate structure;
a first interlayer dielectric (ILD) layer around the first gate structure and the first gate spacers; and
a first interconnect structure at a first side of the first ILD layer and electrically coupled to the first source/drain region.

2. The semiconductor device of claim 1, wherein the second channel layer is vertically stacked over the first channel layer, and a lower surface of the second channel layer facing the first channel layer contacts an upper surface of the first channel layer facing the second channel layer.

3. The semiconductor device of claim 2, wherein the first gate structure comprises:
a gate dielectric material extending along and contacting an upper surface of the second channel layer, sidewalls of the second channel layer, sidewalls of the first channel layer, and a lower surface of the first channel layer, wherein the lower surface of the second channel layer and the upper surface of the first channel layer are free of the gate dielectric material; and
a gate electrode material around the gate dielectric material.

4. The semiconductor device of claim 3, wherein the first semiconductor material is silicon germanium, and the second semiconductor material is silicon.

5. The semiconductor device of claim 4, wherein the first NSFET device is an n-type device, wherein a second thickness of the second channel layer is smaller than a first thickness of the first channel layer.

6. The semiconductor device of claim 4, wherein the first NSFET device is a p-type device, wherein a second thickness of the second channel layer is larger than a first thickness of the first channel layer.

7. The semiconductor device of claim 3, wherein the first NSFET device further comprises inner spacers under the first channel layer and separating the first gate structure from the first source/drain region and the second source/drain region, wherein the lower surface of the first channel layer has a first portion contacting the inner spacers and has a second portion contacting the gate dielectric material, wherein there is a vertical offset between the first portion and the second portion of the lower surface of the first channel layer.

8. The semiconductor device of claim 3, wherein the first NSFET device further comprises a third channel layer vertically stacked over the second channel layer and disposed between the first source/drain region and the second source/drain region, wherein the third channel layer is a layer of the second semiconductor material and is spaced apart from the second channel layer, wherein the gate dielectric material extends along and contacts an upper surface of the third channel layer, sidewalls of the third channel layer, and a lower surface of the third channel layer.

9. The semiconductor device of claim 3, wherein the first NSFET device further comprises a third channel layer and a fourth channel layer that are vertically stacked over the second channel layer and disposed between the first source/drain region and the second source/drain region, wherein the third channel layer and the fourth channel layer are spaced apart from the second channel layer, wherein the third channel layer is a layer of the first semiconductor material and the fourth channel layer is a layer of the second semiconductor material, wherein the first gate structure surrounds the third channel layer and the fourth channel layer.

10. The semiconductor device of claim 9, wherein a lower surface of the fourth channel layer extends along and contacts an upper surface of the third channel layer, wherein the gate dielectric material extends along and contacts an upper surface of the fourth channel layer, sidewalls of the fourth channel layer, sidewalls of the third channel layer, and a lower surface of the third channel layer, wherein the lower surface of the fourth channel layer and the upper surface of the third channel layer are free of the gate dielectric material.

11. The semiconductor device of claim 2, further comprising a second NSFET device, wherein the second NSFET device comprises:
a third source/drain region and a fourth source/drain region;
a third channel layer and a fourth channel layer that are disposed between the third source/drain region and the fourth source/drain region, wherein the fourth channel layer extends along and contacts the third channel layer, wherein the third channel layer is a layer of the first semiconductor material, and the fourth channel layer is a layer of the second semiconductor material;
a second gate structure around the third channel layer and the fourth channel layer;
second gate spacers along opposing sidewalls of the second gate structure;
a second ILD layer around the second gate structure and the second gate spacers; and
a second interconnect structure at a first side of the second ILD layer and electrically coupled to the third source/drain region, wherein the second interconnect structure is bonded to the first interconnect structure.

12. The semiconductor device of claim 11, wherein the first NSFET device is an n-type device, and the second NSFET device is a p-type device.

13. A semiconductor device comprising:
a first nanostructure field-effect transistor (NSFET) device comprising:
a first source/drain region and a second source/drain region;
a first channel region disposed between the first source/drain region and the second source/drain region, wherein the first channel region is a dual-layered channel region that includes a first channel layer and a second channel layer in physical contact with each other, wherein the first channel layer comprises a first semiconductor material and the second channel layer comprises a second semiconductor material different from the first semiconductor material;
a first gate structure around the first channel region; and
a first interconnect structure electrically coupled to the first source/drain region; and
a second NSFET device comprising:
a third source/drain region and a fourth source/drain region;
a second channel region disposed between the third source/drain region and the fourth source/drain region;
a second gate structure around the second channel region; and
a second interconnect structure electrically coupled to the third source/drain region, wherein the second interconnect structure is bonded to the first interconnect structure through direct dielectric-to-dielectric bonding and direct metal-to-metal bonding.

14. The semiconductor device of claim 13, wherein the second channel region is another dual-layered channel region that includes a third channel layer and a fourth channel layer in physical contact with each other, wherein the third channel layer comprises the first semiconductor material and the fourth channel layer comprises the second semiconductor material.

15. The semiconductor device of claim 14, wherein the first semiconductor material is silicon germanium, and the second semiconductor material is silicon.

16. The semiconductor device of claim 15, wherein the first NSFET device is an n-type device, and the first channel layer is thicker than the second channel layer, wherein the second NSFET device is a p-type device, and the third channel layer is thinner than the fourth channel layer.

17. The semiconductor device of claim 13, wherein the second channel region is a single-layered channel region, wherein the second channel region comprises the second semiconductor material.

18. A method of forming a semiconductor device, the method comprising:
forming a first nanostructure field-effect transistor (NSFET) device, wherein forming the first NSFET device comprises:
forming first source/drain regions over a fin;
forming a first channel layer and a second channel layer over the fin and between the first source/drain regions, wherein the second channel layer overlies the first channel layer and is in physical contact with the first channel layer, wherein the first channel layer is formed of a first semiconductor material, and the second channel layer is formed of a second semiconductor material different from the first semiconductor material;
forming a first gate structure around the first channel layer and the second channel layer; and
forming a first interconnect structure at a first side of the first source/drain regions, wherein the first interconnect structure is electrically coupled to the first source/drain regions; and
bonding the first interconnect structure of the first NSFET device to a second interconnect structure of a second NSFET device.

19. The method of claim 18, wherein forming the first NSFET device further comprises forming a third channel layer over the second channel layer and between the first source/drain regions, wherein the third channel layer is spaced apart from the second channel layer, wherein the first gate structure is formed around the first channel layer, the second channel layer, and the third channel layer.

20. The method of claim 18, wherein a first thickness of the first channel layer is different from a second thickness of the second channel layer.
